(19) United States
(12) Patent Application Publication
(10) Pub. No.: US 2025/0335685 A1
(43) Pub. Date: Oct. 30, 2025

(54) Method and Apparatus for Automating Circuit Topology Generation

(71) Applicants: Northeastern University, Boston, MA (US); Washington University, St. Louis, MO (US)

(72) Inventors: Xuan Zhang, Lexington, MA (US); Zehao Dong, Syracuse, NY (US); Weidong Cao, Washington, DC (US); Yixin Chen, Creve Coeur, MO (US)

(21) Appl. No.: 19/204,283

(22) Filed: May 9, 2025

Related U.S. Application Data
(63) Continuation-in-part of application No. 18/900,863, filed on Sep. 29, 2024, now abandoned.
(60) Provisional application No. 63/586,983, filed on Sep. 29, 2023.

(51) Int. Cl. G06F 30/373; G06F 30/27; G06N 3/0455; G06N 3/08

(52) U.S. Cl. CPC G06F 30/373; G06F 30/27; G06N 3/0455; G06N 3/08

(57) ABSTRACT

A method and corresponding apparatus train a circuit topology generator. The method transforms a training circuit topology into a hierarchical graph in a high-dimensional data space. Nodes of the hierarchical graph correspond to selected subgraphs forming a subgraph basis. The selected subgraphs represent circuit elements of the topology. The method converts the hierarchical graph into a directed acyclic graph (DAG) to be processed by a circuit graph neural network (CktGNN) into a latent space. The latent space is a lower-dimensional data space relative to the high-dimensional data space. The method transforms the DAG into an estimated circuit topology via the circuit topology generator and trains the CktGNN and circuit topology generator based on differences between the training circuit topology and estimated circuit topology toward causing the circuit topology generator to converge on the training circuit topology. The trained circuit topology generator may be employed to generate novel circuit topologies, automatically.

### RELATED APPLICATIONS

This application is a continuation-in-part of U.S. application Ser. No. 18/900,863, filed on Sep. 29, 2024, which claims the benefit of U.S. Provisional Application No. 63/586,983, filed on Sep. 29, 2023. The entire teachings of the above applications are incorporated herein by reference.

### GOVERNMENT SUPPORT

This invention was made with government support under Grant No. CCE1942900 awarded by the National Science Foundation. The government has certain rights in the invention.

### BACKGROUND

Graph neural networks (GNNs) use message passing to propagate features between connected nodes. By iteratively aggregating neighboring node features to a center node, GNNs learn node representations encoding their local structure and feature information. These node representations can be further pooled into a graph representation, enabling graph-level tasks, such as graph classification.

### SUMMARY

According to an example embodiment of the present disclosure, a computer-implemented method for training a circuit topology generator comprises transforming a training circuit topology into a hierarchical graph in a high-dimensional data space. Nodes of the hierarchical graph correspond to subgraphs forming a subgraph basis. The selected subgraphs of the subgraph basis represent circuit elements of the training circuit topology. The computer-implemented method further comprises converting the hierarchical graph into a directed acyclic graph (DAG) to be processed by a circuit graph neural network (CktGNN) in a latent space. The latent space is a lower-dimensional data space relative to the high-dimensional data space. The computer-implemented method further comprises transforming the DAG into an estimated circuit topology via the circuit topology generator. The computer-implemented method further comprises training the CktGNN and circuit topology generator based on differences between the training circuit topology and the estimated circuit topology toward causing the circuit topology generator to converge on the training circuit topology.

The training circuit topology may be a schematic of an analog circuit, and the selected subgraphs may represent analog circuit elements.

Converting the hierarchical graph into the DAG may include generating nodes of the DAG and the nodes generated represent non-overlapping combinations of the selected subgraphs.

The computer-implemented method may further comprise encoding the nodes of the hierarchical graph with respective features of the circuit elements represented by the selected subgraphs corresponding thereto. The respective features may be associated with the selected subgraphs in the subgraph basis. The respective features may represent respective electrical characteristics.

Encoding the nodes may include embedding text representing the respective features.

The latent space may be a vectorial space. The computer-implemented method may further comprise encoding the nodes of the hierarchical graph with respective features of the circuit elements represented by the selected subgraphs corresponding thereto, deriving, via the CktGNN, hidden representations from the respective features encoded in the nodes, and encoding the hidden representations derived as vectors in the vectorial space.

Transforming the DAG from the latent space to the estimated circuit topology may include predicting subgraph types and node features of nodes of the DAG and predicting probabilities of connections between the nodes of the DAG via multilayer perceptron (MLP) neural networks.

The CktGNN may include inner GNNs and an outer GNN. Training the CktGNN may include independently learning, via the inner GNNs, representations of the selected subgraphs as node embeddings and performing, via the outer GNN, directed message passing with the learned node embeddings to learn a representation for an entire graph representing the training circuit topology.

Transforming the DAG into the estimated circuit topology may include transforming the DAG into an estimated hierarchical graph in the high-dimensional data space. The estimated hierarchical graph may include estimated nodes representing respective subgraphs from the subgraph basis. Transforming the DAG may further include converting the estimated hierarchical graph into the estimated circuit topology by using the subgraph basis to convert the respective subgraphs to corresponding circuit elements.

The computer-implemented method may further comprise optimizing the DAG in the latent space via at least one optimization method. The at least one optimization method may include at least one of: a Gaussian optimization method, Bayesian optimization method, or other optimization method.

According to another example embodiment, a non-transitory computer-readable medium for training a circuit topology generator has encoded thereon a sequence of instructions which, when loaded and executed by at least one processor, causes the at least one processor to transform a training circuit topology into a hierarchical graph in a high-dimensional data space. Nodes of the hierarchical graph correspond to selected subgraphs forming a subgraph basis. The selected subgraphs of the subgraph basis represent circuit elements of the training circuit topology. The sequence of instructions further causes the at least one processor to convert the hierarchical graph into a directed acyclic graph (DAG) to be processed by a circuit graph neural network (CktGNN) into a latent space. The latent space is a lower-dimensional data space relative to the high-dimensional data space. The sequence of instructions further causes the at least one processor to transform the DAG into an estimated circuit topology via the circuit topology generator. The sequence of instructions further causes the at least one processor to train the CktGNN and circuit topology generator based on differences between the training circuit topology and the estimated circuit topology toward causing the circuit topology generator to converge on the training circuit topology.

Alternative non-transitory computer-readable medium embodiments parallel those described above in connection with the example computer-implemented method embodiment.

According to another example embodiment, a computer-implemented method for automating circuit topology generation comprises generating, automatically via a trained circuit topology generator, a circuit topology based on a latent space and subgraph basis. The latent space is a lower-dimensional data space relative to a higher-dimensional data space. The generating includes generating a hierarchical graph in the higher-dimensional space. The hierarchical graph includes nodes corresponding to subgraphs of the subgraph basis. The computer-implemented method further comprises outputting, by the trained circuit topology generator, the circuit topology generated.

Sampling the latent space may include sampling the latent space, randomly.

Sampling the latent space may include controlling the sampling based on at least one control input. A control input of the at least one control input may represent a feature of an electrical circuit element.

Generating the circuit topology may include including a representation of a circuit element with the feature in the circuit topology generated. The circuit topology generated may be a schematic.

The control input may be a natural language input. The natural language input may be text. The text may be embedded in the latent space.

Generating the circuit topology may include generating the circuit topology for a class of circuit for which the circuit topology generator is trained.

The circuit topology generated may be a novel circuit topology. The novel circuit topology may be different from training circuit topologies of a training dataset used to train the circuit topology generator.

The latent space may represent a statistical distribution of learned representations of training circuit topologies of a circuit class. The circuit topology generated may be associated with the circuit class.

The circuit topology generated may be an analog circuit topology.

It should be understood that example embodiments disclosed herein can be implemented in the form of a method, apparatus, system, or computer readable medium with program codes embodied thereon.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The foregoing will be apparent from the following more particular description of example embodiments, as illustrated in the accompanying drawings in which like reference characters refer to the same parts throughout the different views. The drawings are not necessarily to scale, emphasis instead being placed upon illustrating embodiments.

FIG. 1 is a block diagram of an example embodiment of a computer-based device configured to implement an example embodiment of a computer-implemented method disclosed herein.

FIG. 2A is a flow diagram of a computer-implemented method for training a circuit topology generator.

FIG. 2B is a block diagram of an example embodiment of training flow.

FIG. 2C is a block diagram of an example embodiment of a standardized graph representation of radio-frequency (RF) circuits.

FIG. 3A is a flow diagram of a computer-implemented method for automating circuit topology generation.

FIG. 3B is a block diagram of an example embodiment of topology synthesis flow.

FIG. 4 is a block diagram of an example embodiment of a two-level graph neural network (GNN) framework.

FIGS. 5A and 5B are respective portions of a block diagram of an example embodiment of an architecture of a circuit GNN (CktGNN) disclosed herein.

FIG. 6 is a table of an example embodiment of experimental results.

FIG. 7A is a graph of an example embodiment training efficiency.

FIG. 7B is a graph of an example embodiment of inference efficiency.

FIG. 8 is schematic diagram of an example embodiment of a three-stage operational amplifier (Op-Amp).

FIG. 9A is a schematic diagram of an example embodiment of a differential Op-Amp.

FIG. 9B is a schematic diagram of an example embodiment of single-ended Op-Amp.

FIG. 10 is a schematic diagram of an example embodiment of graph mapping of a three-stage Op-Amp.

FIGS. 11A-D are schematic diagrams of example embodiments of a subgraph basis for operational amplifiers.

FIGS. 12A and 12B are circuits detected by Bayesian Optimization.

FIG. 13 is a block diagram of an example internal structure of a computer optionally within an embodiment disclosed herein.

### DETAILED DESCRIPTION

A description of example embodiments follows.

While example embodiments disclosed herein may be described with regard to an operational amplifier or other circuit element(s), it should be understood that the example embodiments are not limited to an operational amplifier or other circuit element(s).

Electronic design automation of analog circuits has been a longstanding challenge in the integrated circuit field due to the huge design space and complex design trade-offs among circuit specifications. In recent decades, intensive research efforts have mostly been paid to automate the transistor sizing with a given circuit topology. By recognizing the graph nature of circuits, example embodiments presented herein are directed to a Circuit Graph Neural Network (CktGNN) that simultaneously automate the circuit topology generation and device sizing based on encoder-dependent optimization subroutines. Particularly, CktGNN may encode circuit graphs using a two-level graph neural network (GNN) framework (of nested graph neural networks (GNNs)), where circuits are represented as combinations of subgraphs in a known subgraph basis. In this way, an example embodiment may significantly improve design efficiency by reducing a total number of subgraphs to perform message passing. Nonetheless, another roadblock to advancing learning-assisted circuit design automation is a lack of public benchmarks to perform canonical assessment and reproducible research. To tackle the challenge, an example embodiment introduces an Open Circuit Benchmark (OCB), an open-sourced dataset that contains 10K distinct operational amplifiers with carefully-extracted circuit specifications. OCB is also equipped with communicative circuit generation and evaluation capabilities such that it can help to generalize CktGNN to design various analog circuits by producing corresponding datasets. Experiments on OCB show the extraordinary advantages of CktGNN through representation-based optimization frameworks over other recent powerful GNN baselines and human experts' manual designs. An example embodiment may pave the way toward a learning-based open-sourced design automation for analog circuits, as disclosed below

### 1 Introduction

Graphs are ubiquitous to model relational data across disciplines (Gilmer et al., “Neural message passing for quantum chemistry,” In International Conference on Machine Learning, pp. 1263-1272. PMLR, 2017; Duvenaud et al., “Convolutional networks on graphs for learning molecular fingerprints,” Advances in Neural Information Processing Systems, 2015:2224-2232, 2015; Dong et al., “Interpretable drug synergy prediction with graph neural networks for human-ai collaboration in healthcare,” arXiv preprint arXiv: 2105.07082, 2021). Graph neural networks (GNNs) (Kipf & Welling, “Semi-supervised classification with graph convolutional networks,” arXiv preprint arXiv: 1609.02907, 2016; Xu et al., “How powerful are graph neural networks?” In International Conference on Learning Representations, 2019. URL https://openreview.net/forum?id=ryGs6iA5Km; Velickovic et al., “Graph attention networks,” ArXiv, abs/1710.10903, 2018.; You et al., “Graphrnn: Generating realistic graphs with deep auto-regressive models,” In International Conference on Machine Learning, pp. 5708-5717. PMLR, 2018; Scarselli et al., “The graph neural network model,” IEEE transactions on neural networks, 20 (1): 61-80, 2008) have been the de facto standard for representation learning over graph-structured data due to the superior expressiveness and flexibility. In contrast to heuristics using hand-crafted node features (Kriege et al., “A survey on graph kernels,” Applied Network Science, 5 (1): 1-42, 2020) and non-parameterized graph kernels (Vishwanathan et al., “Graph kernels,” Journal of Machine Learning Research, 11:1201-1242, 2010; Shervashidze et al., “Efficient graphlet kernels for large graph comparison,” In Artificial intelligence and statistics, pp. 488-495. PMLR,2009; Borgwardt & Kriegel, “Shortest-path kernels on graphs,” In Fifth IEEE international conference on data mining (ICDM' 05), pp. 8-pp. IEEE, 2005), GNNs incorporate both graph topologies and node features to produce the node/graph-level embeddings by leveraging inductive bias in graphs, which have been extensively used for node/graph classification (Hamilton et al., “Inductive representation learning on large graphs,” In I. Guyon, U. V. Luxburg, S. Bengio, H. Wallach, R. Fergus, S. Vishwanathan, and R. Garnett (eds.), Advances in Neural Information Processing Systems, volume 30. Curran Associates, Inc., 2017. URL https://proceedings.neurips.cc/paper/2017/file/5dd9db5e033da9c6fb5ba83c7a7ebea9-Paper.pdf., 2017; Zhang et al., “An end-to-end deep learning architecture for graph classification. In Proceedings of the AAAI Conference on Artificial Intelligence, volume 32, 2018), graph decoding (Dong et al., “Pace: A parallelizable computation encoder for directed acyclic graphs,” arXiv preprint arXiv: 2203.10304, 2022; Li et al., “Learning deep generative models of graphs,” arXiv preprint arXiv: 1803.03324, 2018), link prediction (Zhang & Chen, “Link prediction based on graph neural networks,” In Proceedings of the 32nd International Conference on Neural Information Processing Systems, pp. 5171-5181, 2018), and etc. Recent successes in GNNs have boosted the requirement for benchmarks to properly evaluate and compare the performance of different GNN architectures. Numerous efforts have been made to produce benchmarks of various graph-structured data. Open Graph Benchmark (OGB) (Hu et al., “Open graph benchmark: Datasets for machine learning on graphs,” arXiv preprint arXiv: 2005.00687, 2020) introduces a collection of realistic and diverse graph datasets for real-world applications including molecular networks, citation networks, source code networks, user-product networks, etc. NAS-Bench-101 (Ying et al., “Nas-bench-101: Towards reproducible neural architecture search,” In International Conference on Machine Learning, pp. 7105-7114. PMLR, 2019) and NAS-Bench-301 (Zela et al., “Surrogatenas benchmarks: Going beyond the limited search spaces of tabularnas benchmarks,” In Tenth International Conference on Learning Representations, pp. 1-36. OpenReview. net, 2022) create directed acyclic graph datasets for surrogate neural architecture search (Elsken et al., “Neural architecture search: A survey,” J. Mach. Learn. Res., 20 (55): 1-21, 2019; Wen et al., 2020). These benchmarks efficiently facilitate substantial and reproducible research, thereby advancing the study of graph representation learning.

Analog circuits, an important type of integrated circuit (IC), are another essential graph modality (directed acyclic graphs, i.e., DAGs). However, since the advent of ICs, labor-intensive manual efforts dominate the analog circuit design process, which is quite time-consuming and cost-ineffective. This problem is further exacerbated by continuous technology scaling where the feature size of transistor devices keeps shrinking and invalidates designs built with older technology. Automated analog circuit design frameworks are, thus, highly in demand. Dominant representation-based approaches (Liu et al., “Parasitic-aware analog circuit sizing with graph neural networks and bayesian optimization,” In 2021 Design, Automation & Test in Europe Conference & Exhibition (DATE), pp. 1372-1377, 2021. doi: 10.23919/DATE51398.2021.9474253.; Wang et al., “Gen-rl circuit designer: Transferable transistor sizing with graph neural networks and reinforcement learning,” In 2020 57th ACM/IEEE Design Automation Conference (DAC), pp. 1-6. IEEE, 2020; Cao et al., “Domain knowledge-based automated analog circuit design with deep reinforcement learning,” 2022a.doi: 10.48550/ARXIV.2202.13185, Cao et al., “Domain knowledge-infused deep learning for automated analog/radio-frequency circuit parameter optimization. In Proceedings of the 59th ACM/IEEE Design Automation Conference, DAC ‘22, pp. 1015-1020, 2022b; Zhang et al., “Circuit-GNN: Graph Neural Networks for Distributed Circuit Design,” In Proceedings of the 36th International Conference on Machine Learning, pp. 7364-7373, 2019a) have recently been developed for analog circuit design automation. Specifically, they optimize device parameters to fulfill desired circuit specifications with a given circuit topology. Typically, GNNs are applied to encode nodes’ embeddings from circuit device features based on the fixed topology, where black-box optimization techniques such as reinforcement learning (Zoph & Le, “Neural architecture search with reinforcement learning,” arXiv preprint arXiv: 1611.01578, 2016) and Bayesian Optimization (Kandasamy et al., “Neural architecture search with bayesian optimisation and optimal transport,” In NeurIPS, 2018) are used to optimize parameterized networks for automated searching of device parameters. While these methods promisingly outperform traditional heuristics (Liu et al., “Hierarchical representations for efficient architecture search,” arXiv preprint arXiv: 1711.00436,2017) in node feature sizing (i.e., device sizing), they are not targeting the circuit topology optimization/generation, which, however, constitutes a useful and challenging task in analog circuit design.

In analogy to neural architecture search (NAS), an example embodiment may encode analog circuits into continuous vectorial space to optimize both the topology and node features. Due to the DAG essence of analog circuits, recent DAG encoders for computation graph optimization tasks are applicable to circuit encoding. However, GRU-based DAG encoders (D-VAE) (Zhang et al., “D-vae: A variational autoencoder for directed acyclic graphs. Advances in neural information processing systems, 32, 2019b) and DAGNN (Thost & Chen, “Directed acyclic graph neural networks,” ArXiv, abs/2101.07965,2021)) use shallow layers to encode computation defined by DAGs, which is insufficient to capture contextualized information in circuits. A transformer-based DAG encoder (Dong et al., “Pace: A parallelizable computation encoder for directed acyclic graphs,” arXiv preprint arXiv: 2203.10304, 2022), however, encodes DAG structures instead of computations. Consequently, an example embodiment may include a circuit graph neural network (CktGNN) to address the above issues. Particularly, CktGNN follows the nested GNN (NGNN) framework (Zhang & Li, “Nested graph neural networks,” Advances in Neural Information Processing Systems, 34, 2021), which represents a graph with rooted subgraphs around nodes and implements message passing between nodes with each node representation encoding the subgraph around it. The core difference is that CktGNN does not extract subgraphs around each node. Instead, a subgraph basis is formulated in advance, and each circuit is modeled as a DAG G where each node represents a subgraph in the basis. Then CktGNN uses two-level GNNs to encode a circuit: the inner GNNs independently learn the representation of each subgraph as node embedding, and the outer GNN further performs directed message passing with learned node embeddings to learn a representation for the entire graph. The inner GNNs enable CktGNN to stack multiple message-passing iterations to increase the expressiveness and parallelizability, while the outer directed message passing operation empowers CktGNN to encode computation of circuits (i.e., circuit performance).

Nonetheless, another barrier to advancing automated circuit design is the lack of public benchmarks for sound empirical evaluations. Research results in the area are hard to reproduce due to the non-unique simulation processes on different circuit simulators and different search space designs. To ameliorate the issue, an example embodiment includes Open Circuit Benchmark (OCB), the first open graph dataset for optimizing both analog circuit topologies and device parameters, which is a good supplement to the growing open-source research in the electronic design automation (EDA) community for IC (Chai et al., “Circuitnet: an open-source dataset for machine learning applications in electronic design automation (eda).” Science China Information Sciences, 65 (12): 227401, September 2022. ISSN 1869-1919. doi: 10.1007/s11432-022-3571-8. URL https://doi.org/10.1007/s11432-022-3571-8, 2022; Hakhamaneshi et al., “Pretraining graph neural networks for few-shot analog circuit modeling and design,” IEEE Transactions on Computer-Aided Design of Integrated Circuits and Systems, 2022). OCB contains 10K distinct operational amplifiers (circuits) whose topologies are modeled as graphs and performance metrics are carefully extracted from circuit simulators. Therefore, the EDA research can be conducted via querying OCB without notoriously tedious circuit reconstructions and simulation processes on the simulator. In addition, there is a plan to open-source codes of the communicative circuit generation and evaluation processes to facilitate further research by producing datasets with arbitrary sizes and various analog circuits. The OCB dataset is also going to be uploaded to OCB to augment the graph machine learning research.

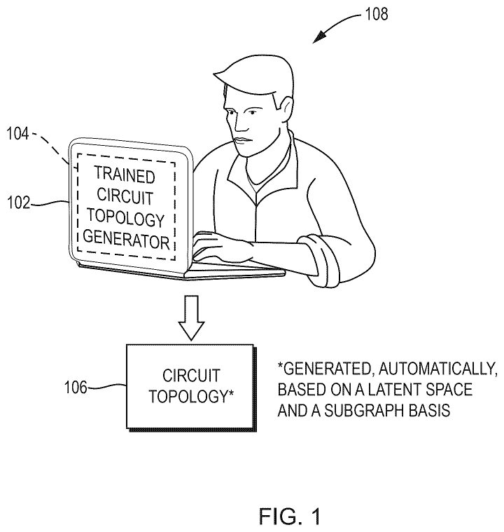

Useful contributions of this disclosure include: 1) a novel two-level GNN, CktGNN, to encode circuits with deep contextualized information, and a GNN framework is disclosed with a pre-designed subgraph basis that can effectively increase the expressiveness and reduce the design space of a very challenging problem-circuit topology generation; 2) introduction of the first circuit benchmark dataset OCB with open-source codes, which can serve as an indispensable tool to advance research in EDA; 3) experimental results on OCB show that CktGNN not only outperforms competitive GNN baselines but also produces high-competitive operational amplifiers compared to human experts' designs, such as the user of FIG. 1, disclosed below.

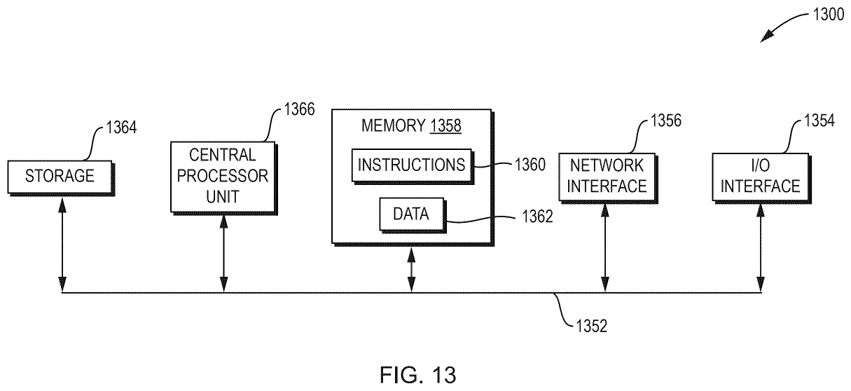

FIG. 1 is a block diagram of an example embodiment of a computer-based device 102 configured to implement an example embodiment of a computer-implemented method disclosed herein. The computer-based device 102 is a laptop in the example embodiment; however, it should be understood that a computer-based device disclosed herein is not limited to a laptop and may be any suitable machine with at least one processor and memory with computer code instructions implemented thereon, such as disclosed further below with regard to FIG. 13 for non-limiting example.

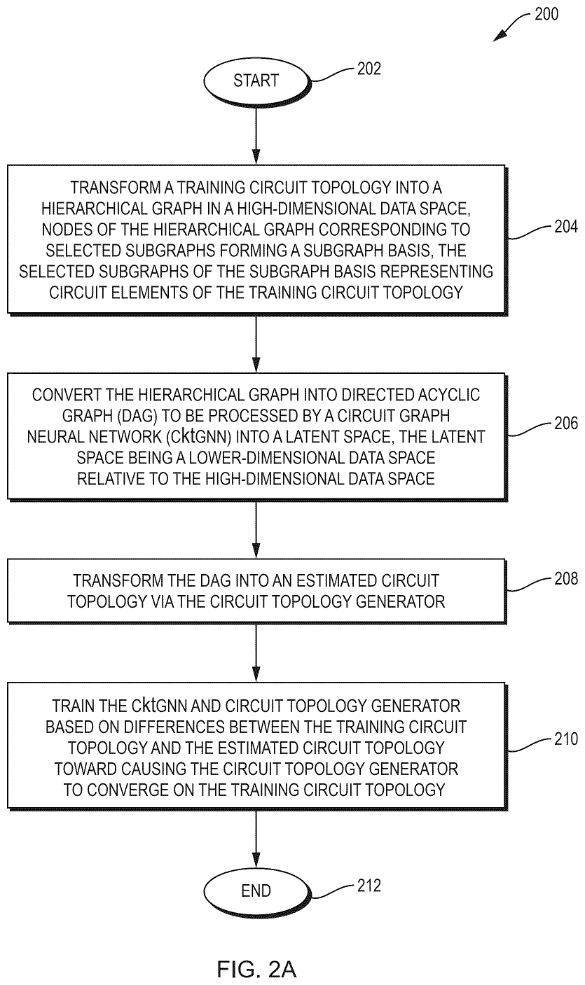

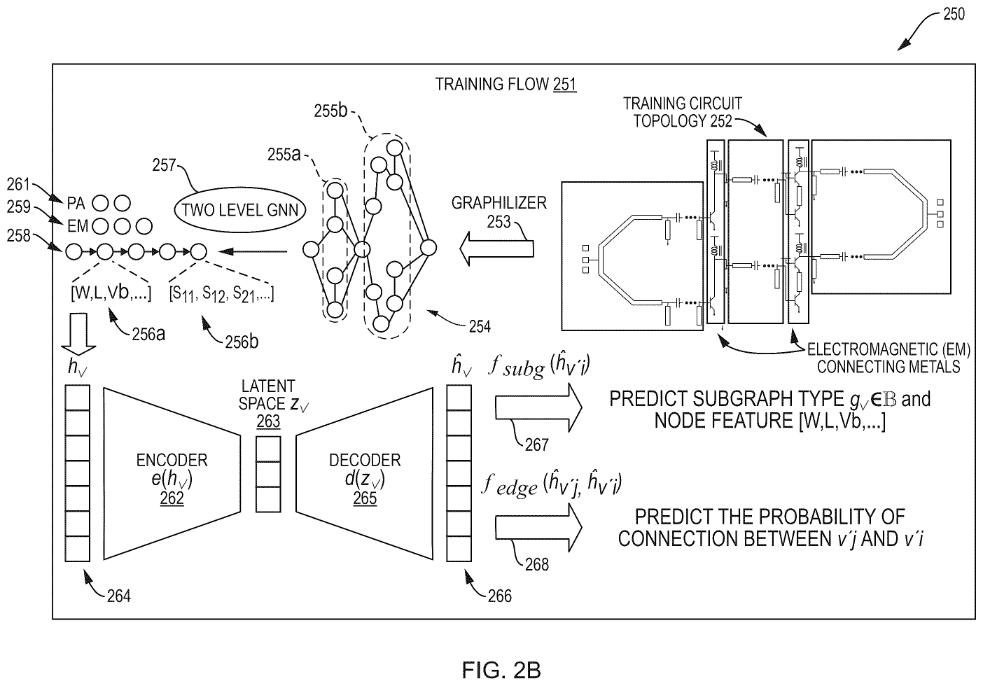

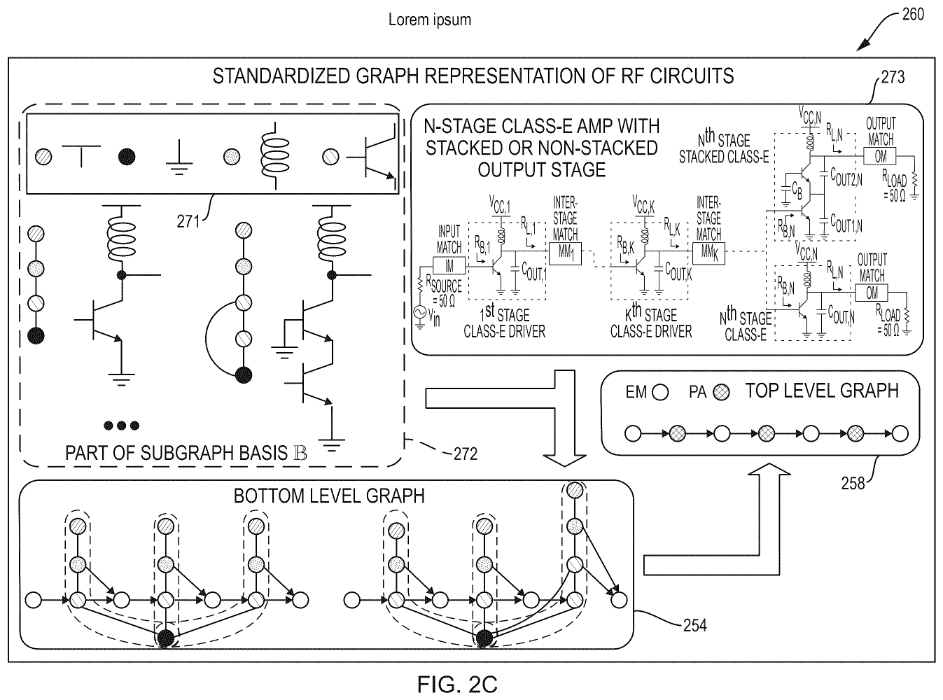

Continuing with reference to FIG. 1, the computer-based device 102 includes a non-transitory computer-readable medium (not shown) for automating circuit topology generation. The non-transitory computer-readable medium has encoded thereon a sequence of instructions which, when loaded and executed by at least one processor (not shown), causes the at least one processor to generate, automatically via a trained circuit topology generator 104, a circuit topology 106 based on a latent space (not shown) and subgraph basis (not shown). The latent space is a lower-dimensional data space relative to a higher-dimensional data space. The generating includes generating a hierarchical graph (not shown) in the higher-dimensional space. The hierarchical graph includes nodes (not shown) corresponding to subgraphs of the subgraph basis. The trained circuit topology generator 102 outputs the circuit topology 106 generated. The circuit topology 106 generated may be a schematic that is used by user 108. The circuit topology 106 generated may be a novel circuit topology. The novel circuit topology may be different from training circuit topologies of a training dataset used to train the circuit topology generator 104, such as disclosed with regard to FIG. 2A.

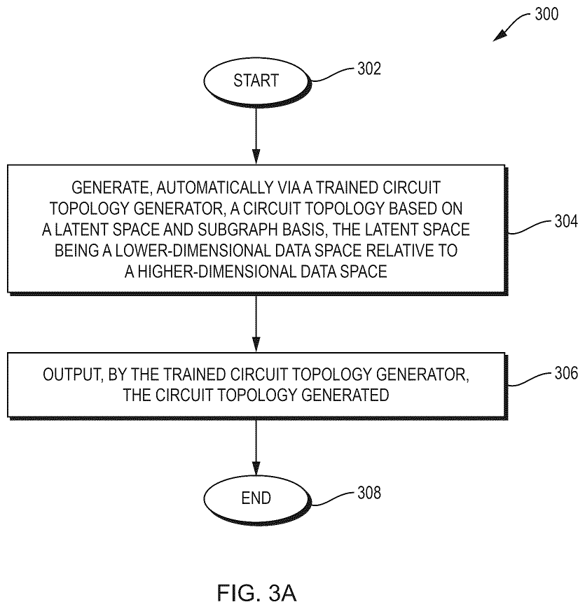

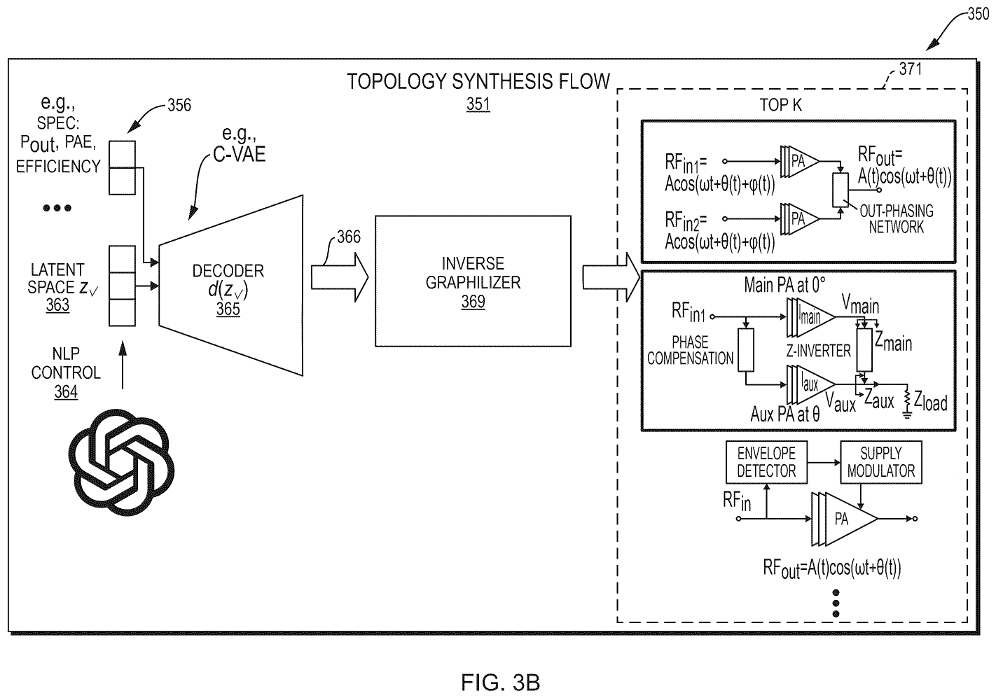

FIG. 2A is a flow diagram of a computer-implemented method 200 for training a circuit topology generator. The computer-implemented method begins (202) and comprises transforming a training circuit topology into a hierarchical graph in a high-dimensional data space (202). Nodes of the hierarchical graph correspond to selected subgraphs forming a subgraph basis. The selected subgraphs of the subgraph basis represent circuit elements of the training circuit topology. The computer-implemented method further comprises converting the hierarchical graph into a directed acyclic graph (DAG) to be processed by a circuit graph neural network (CktGNN) into a latent space (206). The latent space is a lower-dimensional data space relative to the high-dimensional data space. The computer-implemented method further comprises transforming the DAG into an estimated circuit topology via the circuit topology generator (208). The computer-implemented method further comprises training the CktGNN and circuit topology generator based on differences between the training circuit topology and the estimated circuit topology toward causing the circuit topology generator to converge on the training circuit topology (210). The method thereafter ends (212) in the example embodiment. The circuit topology generator may be employed in a method for automating circuit topology generation, such as disclosed below with regard to FIG. 3A, further below.

FIG. 2B is a block diagram 250 of an example embodiment of training flow 251. In the training flow 251, a training circuit topology 252, representing a radio frequency (RF) circuit for non-limiting example, is provided as a design example for training. The training circuit topology 252 is input to a graphilizer 253, disclosed further below. Continuing with reference to FIG. 2B, the graphilizer 253 turns the design, that is, the training circuit topology 252 into a node level graph representation 254 that includes nodes that represent respective circuit components of the training circuit topology 252 via circuit graphs. Such nodes may be grouped as super nodes (255a, 255b) in a directed acyclic graph (DAG) representation 258 disclosed below. The node level graph representation 254 may also be referred to as a flattened graph representation, a full graph representation, or a bottom graph level representation herein. A CktGNN (not shown) may encode such circuit graphs via a two-level graph neural network (GNN) framework (of nested graph neural networks (GNNs)) 257 where circuits are represented as combinations of subgraphs (not shown) in a known subgraph basis (not shown), producing the DAG representation 258 of the node level graph representation 254, in which nodes may be associated with node features (256a, 256b). Such node features (attributes) may include electromagnetic (EM) features of EM nodes 259 and physical characteristics (e.g., device type, device parameter) of physical analog (PA) nodes 261 for non-limiting examples in which s parameter functions of EM structure may be includes in the node features 256b. Physical characteristics may be captured by the node features 256a which may include device size, bias voltage, etc. for non-limiting examples. The DAG representation 258 may be referred to herein as a top-level representation, or hierarchical representation, in which each node is a subgraph.

In the training flow 251, an encoder 262 (e.g., two level GNN 257) may perform a function that converts the node features (256a, 256b) of a subgraph representation 264 into a latent space 263 through GNN computations disclosed further below. A decoder 265 (e.g., inverse graphilizer) may decode the latent space 263 back into a subgraph representation 266 to train a neural network (NN) (not shown) based on predicted subgraph types 267 and another NN predicted probabilities 268 of connections in order to construct a full circuit representation, as disclosed further below. Further technical details regarding the training flow 251 are disclosed further below.

FIG. 2C is a block diagram 260 of an example embodiment of a standardized graph representation of radio-frequency (RF) circuits. In the block diagram 260, a legend 271 is used for types of circuit elements of sub-circuits that may be part of a subgraph basis 272 for non-limiting examples. In the block diagram 260, a power amplifier circuit 273 is shown for non-limiting example, which may be part of the training circuit topology 252 of FIG. 2B, disclosed above. Continuing with reference to FIG. 2C, a bottom level graph, that is the node level graph representation 254 is shown, as well as a top level graph, that is, the DAG representation 258, in which each sub-circuit is abstracted as a supernode.

FIG. 3A is a flow diagram of a computer-implemented method 300 for automating circuit topology generation. The computer-implemented method begins (302) and comprises generating, automatically via a trained circuit topology generator, a circuit topology based on a latent space and subgraph basis (304). The latent space is a lower-dimensional data space relative to a higher-dimensional data space. The generating includes generating a hierarchical graph in the higher-dimensional space. The hierarchical graph includes nodes corresponding to subgraphs of the subgraph basis. The computer-implemented method further comprises outputting, by the trained circuit topology generator, the circuit topology generated (306). The computer-implemented method thereafter ends (308) in the example embodiment.

FIG. 3B is a block diagram 350 of an example embodiment of topology synthesis flow 351, in which a decoder 365 may decode the latent space 363 back into a subgraph representation 366 to input to an inverse graphilizer 369 in order to construct a full circuit representation 371, as disclosed further below. The decoder 365 may employ node features 365 that may define circuit specifications, such as a range of gain, for non-limiting example. In the example embodiment of FIG. 3B, natural language processing (NLP) control 364 may be employed as a text embedder for non-limiting example, to inject into the latent space 363. Further technical details regarding the topology synthesis flow 351 are disclosed further below.

### 2 Related Works

### 2.1 Graph Neural Networks

### GNNs for DAGs

Directed acyclic graphs (DAGs) are another ubiquitous graph modality in the real world. Instead of implementing message passing across all nodes simultaneously, DAG GNNs (encoders) such as D-VAE (Zhang et al., “D-vae: A variational, autoencoder for directed acyclic graphs. Advances in neural information processing systems, 32, 2019b) and DAGNN (Thost & Chen, “Directed acyclic graph neural networks,” ArXiv, abs/2101.07965, 2021) sequentially encode nodes following the topological order. Message passing order thus respects the computation dependency defined by DAGs. Similarly, S-VAE (Bowman et al., “Generating sentences from a continuous space,” In Proceedings of The 20th SIGNLL Conference on Computational Natural Language Learning, pp. 10-21, 2016) represents DAGs as sequences of node strings of the node type and adjacency vector of each node and then applies a GRU-based RNN to the topologically sorted sequence to learn the DAG representation. To improve the encoding efficiency, PACE (Dong et al., “ace: A parallelizable computation encoder for directed acyclic graphs,” arXiv preprint arXiv: 2203.10304, 2022) encodes the node orders in the positional encoding and processes nodes simultaneously under a Transformer (Vaswani et al., “Attention is all you need,” In Proceedings of the 31st International Conference on Neural Information Processing Systems, pp. 6000-6010, 2017) architecture.

### 2.2 Automated Analog Circuit Design

### Design Automation Methods for Device Sizing

Intensive research efforts have been paid in the past decades to automate the analog circuit design at the pre-layout level, i.e., finding the optimal device parameters to achieve the desired circuit specifications. Early explorations focus on optimization-based methods, including Bayesian Optimization (Lyu et al., “Batch bayesian optimization via multi-objective acquisition ensemble for automated analog circuit design,” In International conference on machine learning, pp. 3306-3314. PMLR, 2018), Geometric Programming (Colleran et al., “Optimization of Phase-Locked Loop Circuits via Geometric Programming,” In Proceedings of the IEEE 2003 Custom Integrated Circuits Conference, 2003., pp. 377-380, 2003), and Genetic Algorithms (Liu et al., “Analog Circuit Optimization System Based on Hybrid Evolutionary Algorithms,” Integration, 42 (2): 137-148, 2009). Recently, learning-based methods such as supervised learning methods (Zhang et al., “Circuit-GNN: Graph Neural Networks for Distributed Circuit Design,”. In Proceedings of the 36th International Conference on Machine Learning, pp. 7364-7373, 2019a) and reinforcement learning methods (Wang et al., “Gcn-rl circuit designer: Transferable transistor sizing with graph neural networks and reinforcement learning,” In 2020 57th ACM/IEEE Design Automation Conference (DAC), pp. 1-6. IEEE, 2020; Li et al., “A circuit attention network-based actor-critic learning approach to robust analog transistor sizing,” In 2021 ACM/IEEE 3rd Workshop on Machine Learning for CAD (MLCAD), pp. 1-6. IEEE, 2021; Cao et al., “Domain knowledge-based automated analog circuit design with deep reinforcement learning,”. doi: 10.48550/ARXIV.2202.13185.2022a; Cao et al., “Domain knowledge-infused deep learning for automated analog/radio-frequency circuit parameter optimization,” In Proceedings of the 59th ACM/IEEE Design Automation Conference, DAC '22, pp. 1015-1020,) have emerged as promising alternatives. Supervised learning methods aim to learn the underlying static mapping relationship between the device parameters and circuit specifications. Reinforcement learning methods, on the other hand, endeavor to find a dynamic programming policy to update device parameters in an action space according to the observations from the state space of the given circuit. Despite their great promise, all these prior arts have been limited to optimizing the device parameters with a given analog circuit topology. There are only a few efforts (e.g., Genetic Algorithms (Das & Vemuri, “An automated passive analog circuit synthesis framework using genetic algorithms,” In IEEE Computer Society Annual Symposium on VLSI (ISVLSI '07), pp. 145-152, 2007. doi: 10.1109/ISVLSI.2007.22.)) to tackle another very challenging yet more important problem, i.e., circuit topology synthesis. These works leverage genetic operations such as crossover and mutation to randomly generate circuit topologies and do not sufficiently incorporate practical constraints from feasible circuit topologies into the generation process. Therefore, most of the generated topologies are often non-functional and ill-posed. Conventionally, a newly useful analog circuit topology is manually invented by human experts who have rich domain knowledge within several weeks or months. Work disclosed herein focuses on efficiently and accurately automating circuit topology generation, based on which the device parameters for the circuit topology are further optimized.

### Graph Learning for Analog Circuit Design Automation

With the increasing popularity of GNNs in various domains, researchers have recently applied GNNs to model circuit structures as a circuit topology resembles a graph very much. Given a circuit structure, the devices in the circuit can be treated as graph vertices, and the electrical connections between devices can be abstracted as edges between vertices. Inspired by this homogeneity between the circuit topology and graph, several prior arts have explored GNNs to automate the device sizing for analog circuits. A supervised learning method (Zhang et al., “Circuit-GNN: Graph Neural Networks for Distributed Circuit Design,” In Proceedings of the 36th International Conference on Machine Learning, pp. 7364-7373, 2019a) is applied to learn the geometric parameters of passive devices with a customized circuit-topology-based GNN. And reinforcement learning-based methods (Wang et al., “Gen-rl circuit designer: Transferable transistor sizing with graph neural networks and reinforcement learning,”. In 2020 57th ACM/IEEE Design Automation Conference (DAC), pp. 1-6. IEEE, 2020; Cao et al., “Domain knowledge-infused deep learning for automated analog/radio-frequency circuit parameter optimization,” In Proceedings of the 59th ACM/IEEE Design Automation Conference, DAC '22, pp. 1015-1020, 2022b) propose circuit-topology-based policy networks to search for optimal device parameters to fulfill desired circuit specifications. Distinctive from these prior arts, an example embodiment disclosed herein harnesses a two-level GNN encoder to simultaneously optimize circuit topologies and device features.

### 3 Circuit Graph Neural Network

In this section, an example embodiment of a CktGNN model is disclosed, constructed upon a two-level GNN framework with a subgraph basis to reduce the topology search space for the downstream optimization algorithm. The graph-level learning task is considered. Given a graph G=(V, E), where V={1, 2, . . . , n} is the node set with |V|=n and E∈V×V is the edge set. For each node i in a graph G, let N(v)={u∈V|(u, v)∈E} denote the set of neighboring nodes of v.

3.1 Two-Level GNN Framework with a Subgraph Basis

Most undirected GNNs follow the message passing framework that iteratively updates the nodes' representation by propagating information from the neighborhood into the center node. Let ht denote the representation of v at time stamp, the message passing framework is given by:

$${a}_{v}^{t + 1} = 𝒜 ( \{ {h}_{u}^{t} \vert ( u , v ) ∈ E \} ) {h}_{v}^{t + 1} = 𝒰 ( {h}_{u}^{t} , {a}_{v}^{t + 1} ) \qquad ( 1 )$$

Here, A is an aggregation function on the multiset of representations of nodes in N(v), and U is an update function. Given an undirected graph G, GNNs perform the message passing over all nodes simultaneously. For a DAG G, the message passing progresses following the dependency of nodes in DAG G. That is, a node v's representation is not updated until all of its predecessors are processed.

It has been shown that the message passing scheme mimics the 1-dimensional Weisfeiler-Lehman (1-WL) algorithm (Leman & Weisfeiler, “A reduction of a graph to a canonical form and an algebra arising during this reduction,” Nauchno-Technicheskaya Informatsiya, 2 (9): 12-16, 1968). Then, the learned node representation encodes a rooted subtree around each node. And GNNs exploit the homophily as a strong inductive bias in graph learning tasks, where graphs with common substructures will have similar predictions. However, encoding rooted subtrees limits the representation ability, and the expressive power of GNNs is upper-bounded by the 1-WL test (Xu et al., “How powerful are graph neural networks?” In International Conference on Learning Representations, 2019. URL https: //openreview.net/forum?id=ryGs6iA5Km, 2019). For instance, message passing GNNs fail to differentiate d-regular graphs (Chen et al., “On the equivalence between graph isomorphism testing and function approximation with gnns,” Advances in neural information processing systems, 32, 2019; Murphy et al., “Relational pooling for graph representations,” In International Conference on Machine Learning, pp. 4663-4673. PMLR, 2019).

To improve the expressive ability, (Zhang & Li, “Nested graph neural networks,” Advances in Neural Information Processing Systems, 34, 2021) introduces a two-level GNN framework, NGNN, that encodes the general local rooted subgraph around each node instead of a subtree. Concretely, given a graph G, h-hop rooted subgraph gᵥ^{h} around each node v is extracted. Then, inner GNNs are independently applied to these subgraphs {gᵥ^{h}|v∈} and the learned graph representation of gᵥ^{h} is used as the input embedding of node v to the outer GNN. After that, the outer GNN applies graph pooling to get a graph representation. The NGNN framework is strictly more powerful than 1-WL and can distinguish almost all d-regular graphs. However, the two-level GNN framework cannot be applied to DAG encoders (GNNs).

Hence, a two-level GNN framework is introduced with an (ordered) subgraph basis, to restrict subgraphs for inner message passing in the given subgraph basis and apply it to the circuit (DAG) encoding problems in order to reduce the topology search space and increase the expressive ability.

Definition 3.1 (Ordered subgraph basis) An ordered subgraph basis [symbol] ={g₁, g₂, . . . , g_{K}} is a set of subgraphs with a total order o. For ∀g₁, g₂∈ [symbol] , g₁<g₂ if and only if o(g₁)<o(g₂).

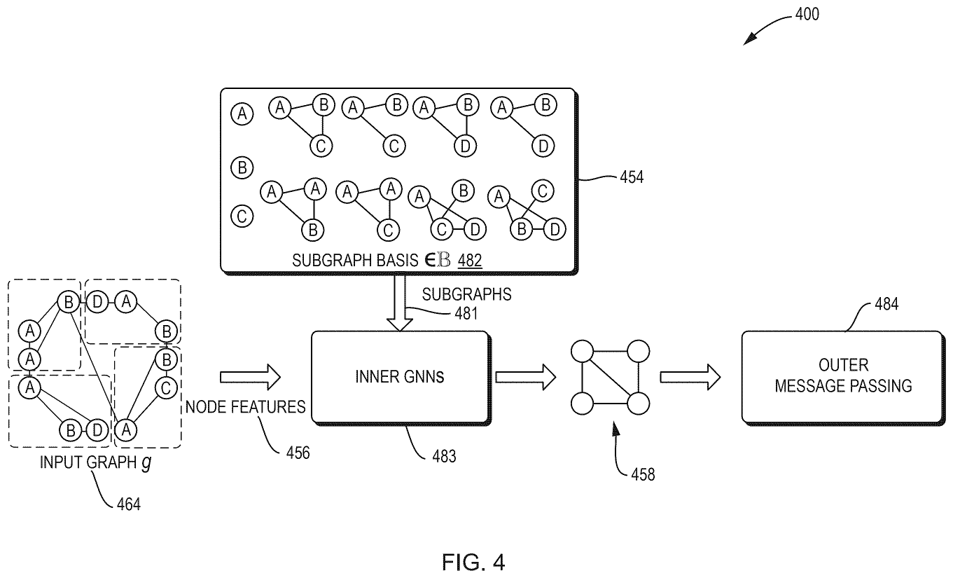

FIG. 4 is a block diagram 400 of an example embodiment of a two-level GNN framework. Given a graph (454 and an ordered subgraph basis [symbol] 482, the rules to extract subgraphs 481 for inner GNNs 483 to learn representations are as follows: 1) For node v∈G, suppose it belongs to multiple subgraphs g₁^{v}, . . . gₘ^{v}∈ [symbol] , then the selected subgraph to perform (inner) message passing is gₕ^{v} =argmax_{i=1,2 . . . m}^{o} (gᵢ^{v}). 2). If connected nodes v and u select the same subgraph gₕ∈B, v and u are merged and the representation of subgraph gₕ is used as the feature of the merged node when performing the outer message passing 484. The inner GNNs 483 may employ node features 456 (e.g., parameters associated with circuit elements) of nodes of an input graph g 464 and the subgraph basis [symbol] 482 to produce a hierarchical graph 458 that may be referred to as a top level, in which nodes interact as a unit. In the example embodiment of FIG. 4, the input graph 484 may represent an input circuit that is converted to the hierarchical graph 458, using a circuit graphilizer (not shown) as disclosed herein. The CktGNN may use the inner GNNs 483 to encode to encode each subgraph as a node in the hierarchical graph 458. The outer message passing 484 may be used to learn a circuit representation based on the hierarchical graph 458. Further technical details are disclosed further below in which it is shown that two-level GNNs can be more powerful than 1-WL in Appendix B, disclosed further below.

### 3.2 THE CktGNN Model

Next, the CktGNN model is introduced for the circuit (i.e., DAGs) automation problem which requires optimizing the circuit topology and node features at the same time. The CktGNN model may optimize circuits with arbitrary topology. Given a circuit G=(V, E), each node v∈V has a node type xᵢ and node features xₛ, where xᵢ denotes the device type in a circuit (i.e., resistor, capacitor, and etc.), and xₛ are the categorical or continuous features of the corresponding device.

Due to the similarity between the circuit automation problem and neural architecture search (NAS), potential solutions naturally come from advancements in neural architecture search, where two gradient-based frameworks have achieved impressive results in DAG architecture learning: 1) The VAE framework (Dong et al., “Pace: A parallelizable computation encoder for directed acyclic graphs,” arXiv preprint arXiv: 2203.10304, 2022; Zhang et al., “D-vae: A variational autoencoder for directed acyclic graphs. Advances in neural information processing systems, 32, 2019b) uses a GRU-based (or Transformer-based) encoder to map DAGs into vectorial space and then trains the model with a VAE loss. 2) NAS-subroutine-based framework develops DAG encoders and implements encoding-dependent subroutines such as perturb-architecture subroutines (Real et al., “Regularized evolution for image classifier architecture search,” In Proceedings of the aaai conference on artificial intelligence, volume 33, pp. 4780-4789, 2019; White et al., “Local search is state of the art for nas benchmarks,” arXiv preprint arXiv: 2005.02960, 2020) and train-predictor-model subroutines (Wen et al., “Neural predictor for neural architecture search,” In European Conference on Computer Vision, pp. 660-676. Springer, 2020; Shi et al., “Bridging the gap between sample-based and one-shot neural architecture search with bonas,” arXiv preprint arXiv: 1911.09336, 2019, 2019). As the NAS-subroutine-based framework usually requires a relatively large-size training dataset, yet the large-scale performance simulation of circuits can be time-consuming, thus, an example embodiment may resort to the VAE framework.

Due to the complexity of circuit (DAG) structures and the huge size of the circuit design space (see Appendix A), the circuit automation problem is typically a highly non-convex, challenging optimization problem. Thus, the GRU-based encoders that use shallow layers to encode complex DAG architectures are not sufficient to capture complicated contextualized information of node features and topologies. To address these limitations, an example embodiment of CktGNN model is introduced, as disclosed below.

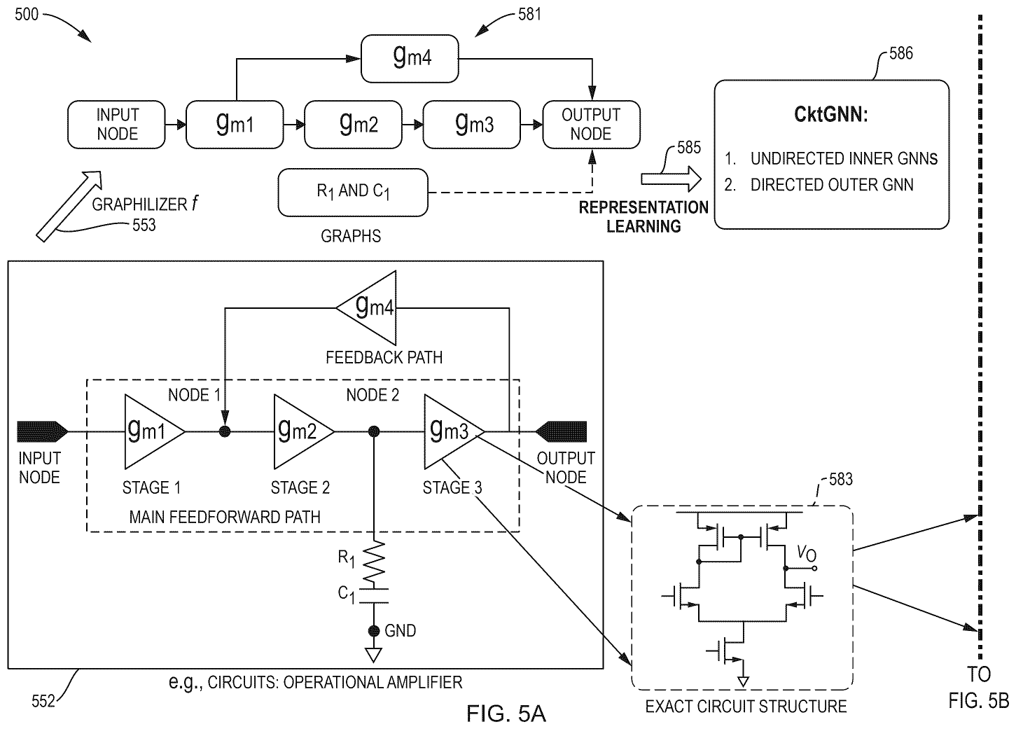

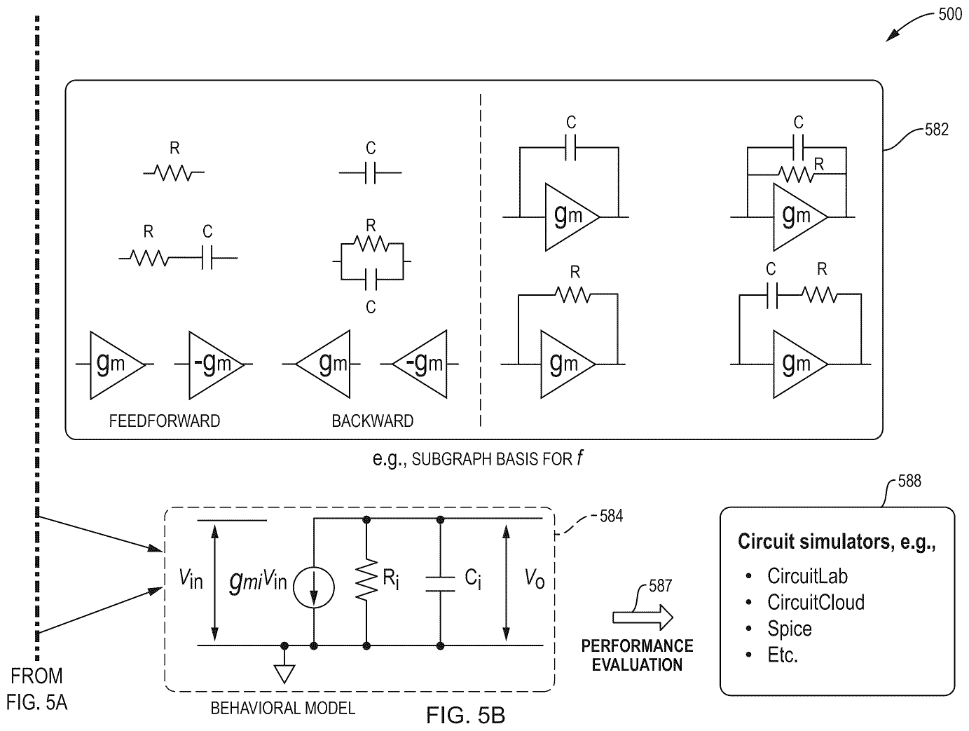

FIGS. 5A and 5B are respective portions of a block diagram 500 of an example embodiment of an architecture of a CktGNN disclosed herein. The key idea is to decompose the input circuit 552 as combinations of non-overlapping subgraphs 581 in the subgraph basis [symbol] 582. Sub-circuit modules of the input circuit 552 may be encoded as functional sub-structures based on their respective exact circuit structure 583 and using their respective behavioral model 584. After the graph transformation process (i.e. graphilizer f 553), each node in the transformed DAG G′=(V′, E′) represents a subgraph in the input graph (circuit). Then, the representation of a circuit is learned 585 in the two-level GNN framework 586. A performance evaluation 587 may be performed using one or more circuit simulators 588, such as disclosed further below.

Each node v′∈V′ in the transformed DAG G′ corresponds to a subgraph g_{v′} in the input graph. CktGNN treats g_{v′} as an undirected graph and uses inner GNNs to learn the subgraph representation h_{v′}, and each inner GNN consists of multiple undirected message passing layers followed by a graph pooling layer to summarize a subgraph representation. Such a technique enables inner GNNs to capture the contextualized information within each subgraph, thereby increasing the representation ability. In addition, undirected message passing also provides better parallelizability than directed message passing, which increases encoding efficiency.

In the outer level GNN, CktGNN performs directed message passing where the aggregation function A uses a gated summation, and the update function (uses a gated recurrent unit (GRU):

$${a}_{{v}^{′}} = 𝒜 ( \{ {z}_{{u}^{′}} \vert {u}^{′} ∈ 𝒩 ( {v}^{′} ) \} ) = {\sum }_{{u}^{′} ∈ 𝒩 ( {v}^{′} )} g ( {z}_{{u}^{′}} ) ⊗ m ( {z}_{{u}^{′}} ) , \qquad ( 2 )$$

$${z}_{{v}^{′}} = 𝒰 ( concat ( {x}_{{v}^{′}}^{′} {h}_{{v}^{′}} ) , {a}_{{v}^{′}} ) . \qquad ( 3 )$$

Here, z_{v′} is the hidden representation of node v′ in the transformed DAG G, m is a mapping network and g is a gating network. In the GRU, x′_{v′} is the one-hot encoding of the subgraph type, and h_{v′} is the corresponding subgraph representation learned by inner GNNs. The outer level GNN processes nodes in the transformed DAG G′ following the topological order and uses the hidden representation of the output node as the graph representation.

### 3.3 Discussions

### The Injectivity of Graph Transformation Process

Since CktGNN is constructed upon a graphilizer f: G→G that converts input circuits G to DAGs G′ whose nodes v′ represent non-overlapping subgraphs in G, it's worth discussing the injectivity of f. If f(G) is not unique, CktGNN will map the same input circuit (DAG G) to different transformed G′, thereby learning different representations for the same input G.

Theorem 3.2 Let subgraph basis [symbol] contain every subgraph of size 1. There exists an injective graph transformation f, if each subgraph g_{v′}∈ [symbol] has only one node to be the head (tail) of a directed edge whose tail (head) is outside the subgraph g_{v′}.

Theorem 3.2 is proven in Appendix C, disclosed further below. The theorem implies that f exists when subgraph basis [symbol] contains every subgraph of size 1 and characterizes conditions when the injectivity concern is satisfied. The proof shows that an injective f can be constructed based on the order function o over the basis [symbol] . The condition in the Theorem holds in various real-world applications including circuit automation and neural architecture search. For instance, FIGS. 5A and 5B present an ordered subgraph basis that satisfies the condition for the general operational amplifiers (circuits), and operational amplifiers and the corresponding subgraph basis is introduced in Appendix A, disclosed further below.

### Comparison to Related Works.

The proposed CktGNN model extends the NGNN technique (i.e., two-level GNN framework) (Zhang & Li, “Nested graph neural networks,” Advances in Neural Information Processing Systems, 34, 2021) to the directed message passing framework for DAG encoding problem. In contrast to NGNN which extracts a rooted subgraph structure around each node within which inner GNNs perform message passing to learn the subgraph representation, CktGNN only uses inner GNNs to learn representations of non-overlapping subgraphs in a known ordered subgraph basis [symbol] . Two main advantages come from the framework over GRU-based DAG encoders (i.e., D-VAE and DAGNN). 1) The topology within subgraphs is automatically embedded once the subgraph type is encoded in CktGNN, which significantly reduces the size of the topology search space. 2) The inner GNNs in CktGNN help to capture the contextualized information within each subgraph, while GNNs in GRU-based DAG encoders are usually too shallow to provide sufficient representative ability.

### 4 Open Circuit Benchmark

For non-limiting example, operational amplifiers (Op-Amps) may be taken to build an open circuit benchmark as they are not only one of the most difficult analog circuits to design in the world, but also are the common benchmarks used by prior arts (Wang et al., “Gcn-rl circuit designer: Transferable transistor sizing with graph neural networks and reinforcement learning,” In 2020 57th ACM/IEEE Design Automation Conference (DAC), pp. 1-6. IEEE, 2020; Li et al., “A circuit attention network-based actor-critic learning approach to robust analog transistor sizing,” In 2021 ACM/IEEE 3rd Workshop on Machine Learning for CAD (MLCAD), pp. 1-6. IEEE, 2021; Cao et al., “Domain knowledge-infused deep learning for automated analog/radio-frequency circuit parameter optimization,” In Proceedings of the 59th ACM/IEEE Design Automation Conference, DAC '22, pp. 1015-1020, 2022b) to evaluate the performance of the proposed methods. The benchmark equips with communicative circuit generation and evaluation capabilities such that it can also be applied to incorporate a broad range of analog circuits for the evaluations of various design automation methods. To enable such great capabilities, two notable features are proposed and introduced below.

Converting Circuits into Graphs

An acyclic graph mapping method may be leveraged by abstracting a complex circuit structure to several simple low-level functional sub-structures, which is similar to the standard synthesis of modern digital circuits. Such a conversion method is thus scalable to large-scale analog circuits with thousands of devices while effectively avoiding cycles in graph converting. To illustrate this general mapping idea, the Op-Amps may be taken in the benchmark as an example (see the left upper corner in FIG. 5A). For an N-stage Op-Amp (N=2, 3), it consists of N single-stage Op-Amps in the main feedforward path (i.e., from the input direction to the output direction) and several feedback paths (i.e., vice versa) with different sub-circuit modules. All single-stage Op-Amps and sub-circuit modules are encoded as functional sub-structures by using their behavioral models (Lu et al., “Automated compensation scheme design for operational amplifier via bayesian optimization,” In 2021 58th ACM/IEEE Design Automation Conference (DAC), pp. 517-522, 2021. doi: 10.1109/DAC18074.2021.9586306, 2021). In this way, each functional sub-structures can be significantly simplified without using its exact yet complex circuit structure. For instance, a single-stage Op-Amp with tens of transistors can be modeled as a voltage-controlled current source (VCCS, gₘ) with a pair of parasitic capacitor C and resistor R. Instead of using these functional sub-structures as graph vertices, they may be leveraged as graph edges while the connection point (e.g., node 1 and node 2) between these sub-structures is taken as vertices. Meanwhile, an example embodiment may unify both feedforward and feedback directions as feedforward directions but distinguish them by adding a polarity (e.g., ‘+’ for feedforward and ‘-’ for feedback) on device parameters (e.g., gₘ+ or gₘ−). In this way, an arbitrary Op-Amp can be efficiently converted into an acyclic graph as shown in FIGS. 5A and 5B. Inversely, a newly-generated circuit topology from graph sampling can be converted back into the corresponding Op-Amp by using a conversion-back process from the graph and functional sub-structures to real circuits.

Interacting with Circuit Simulators

Another important feature of an example embodiment of a circuit benchmark disclosed herein is that it can directly interact with a circuit simulator to evaluate the performance of a generated Op-Amp in real-time. Once a circuit topology is generated from an example embodiment of graph sampling, a tailored Python script can translate it into a circuit netlist. A circuit netlist is a standard hardware description of a circuit, based on which the circuit simulator can perform a simulation (evaluation) to extract the circuit specifications, e.g., gain, phase margin, and bandwidth for Op-Amps. This process can be inherently integrated into a Python environment as both open-sourced and commercial circuit simulators support command-line operations. This conversion-generation-simulation loop may be leveraged to generate 10,000 different Op-Amps with detailed circuit specifications. Note that in in an example embodiment of a dataset, the topologies of Op-Amps are not always distinct from each other. Some Op-Amps have the same topology but with different device parameters. However, an example embodiment of the benchmark is friendly to augment other analog circuits such as filters if corresponding circuit-graph mapping methods are built.

### 5 Experiments

### 5.1 Dataset, Baselines, and Tasks

### Dataset

For non-limiting example, a circuit dataset containing 10,000 operational amplifiers (circuits) is employed, obtained from the circuit generation process of OCB. Nodes in a circuit (graph) are sampled from C (capacitor), R (resistor), and single-stage Op-Amps with different polarities (positive or negative) and directions (feedforward or feedback). Node features are then determined based on the node type: resistor R has a specification from 10⁵ to 10⁷ Ohm, capacitor C has a specification from 10⁻¹⁴ to 10⁻¹² F, and the single-stage Op-Amp has a specification (transconductance, gₘ) from 10⁻⁴ to 10⁻² S. For each circuit, the circuit simulator of OCB performs careful simulations to get the graph properties (circuit specifications): DC gain (Gain), bandwidth (BW), and phase margin (PM), which characterize the circuit performance from different perspectives. Then the Figure of Merit (FoM) which is an indicator of the circuit's overall performance is computed from Gain, BW, and PM. Details are available in Appendix B, disclosed further below.

### Baselines

CktGNN was compared with GNN baselines including: 1) widely adopted (undirected) GNNs: GCN (Kipf & Welling, “Semi-supervised classification with graph convolutional networks,” arXiv preprint arXiv: 1609.02907, 2016), GIN (Xu et al., “How powerful are graph neural networks?” In International Conference on Learning Representations, 2019. URL https://openreview.net/forum?id=ryGs6iA5Km.2019), NGNN (Zhang & Li, “Nested graph neural networks,” Advances in Neural Information Processing Systems, 34, 2021) and Graphormer (Ying et al., “Do transformers really perform bad for graph representation?” arXiv preprint arXiv: 2106.05234, 2021); 2) dominant DAG encoders (directed GNNs): D-VAE (Zhang et al., “D-vae: A variational autoencoder for directed acyclic graphs,” Advances in neural information processing systems, 32, 2019b), DAGNN (Thost & Chen, “Directed acyclic graph neural networks,” ArXiv, abs/2101.07965,2021) and PACE (Dong et al., “Pace: A parallelizable computation encoder for directed acyclic graphs,” arXiv preprint arXiv: 2203.10304,2022). Baseline settings are provided in Appendix D, disclosed further below.

### Tasks

CktGNN was compared against baselines on the following three tasks to evaluate the expressiveness, efficiency, and real-world impact: (1) Predictive performance and topology reconstruction accuracy: A test for how well the learned graph representation encodes information to predict the graph properties (i.e., Gain, BW, PM, FoM) and reconstruct the input circuit topology may be performed. (2) Circuit encoding efficiency: This task compares the training/inference time to characterize the efficiency of the circuit (DAG) encoders. (3) Effectiveness in real-world electronic circuit design automation: For the purpose of circuit generation, a test may be performed of the proportion that the decoder in the VAE architecture can generate valid DAGs, circuits, and new circuits that are never seen in the training set. Furthermore, for the purpose of automated circuit design, and Bayesian Optimization may be performed and a comparison of the overall performance (i.e., FoM) of the detected circuit topology and specifications may be performed.

### 5.2 Predictive Performance and Topology Reconstruction Accuracy

In the experiment, the expressive ability of circuit encoders was tested by evaluating the predictivity of the learned graph representation. As the encoder with more expressive ability can better distinguish circuits (graphs) with different topologies and specifications, circuits with similar properties (Gain, BW, PM, or FoM) can be mapped to close representations. Following experimental settings of D-VAE (so as DAGNN and PACE), training of sparse Gaussian Process (SGP) regression models (Snelson & Ghahramani, “Sparse gaussian processes using pseudo-inputs,” Advances in neural information processing systems, 18:1257-1264,2005) was performed to predict circuit properties based on learned representations. In addition, a characterization of the complexity of topology space to encode by measuring the reconstruction accuracy of the circuit topology was performed. The results are included in FIG. 6, disclosed below.

FIG. 6 is a table 600 of an example embodiment of experimental results showing predictive performance and topology reconstruction accuracy. Table 600 may be referred to interchangeably herein as Table 1. Experimental results illustrate that CktGNN consistently achieves state-of-art performance in predicting circuit properties. In analogy to D-VAE, it was found that CktGNN encodes computation (i.e., circuit performance) instead of graph structures when the map between subgraph structure and their defined computation is injective for subgraphs in the basis [symbol] . Compared to DAG encoders D-VAE and DAGNN that encodes circuit, inner GNNs in CktGNN enables more message passing iterations to better encode the complicated contextualized information in circuits. On the other hand, PACE, undirected GNNs, and graph Transformers inherently encode graph structures, hence, the latent graph representation space of CktGNN is smoother w.r.t the circuit performance. Furthermore, it was also found that CktGNN significantly improves the topology reconstruction accuracy. Such an observation is consistent with the purpose of CktGNN (see Section 3.2) to reduce the topology search space.

### 5.3 Circuit Encoding Efficiency

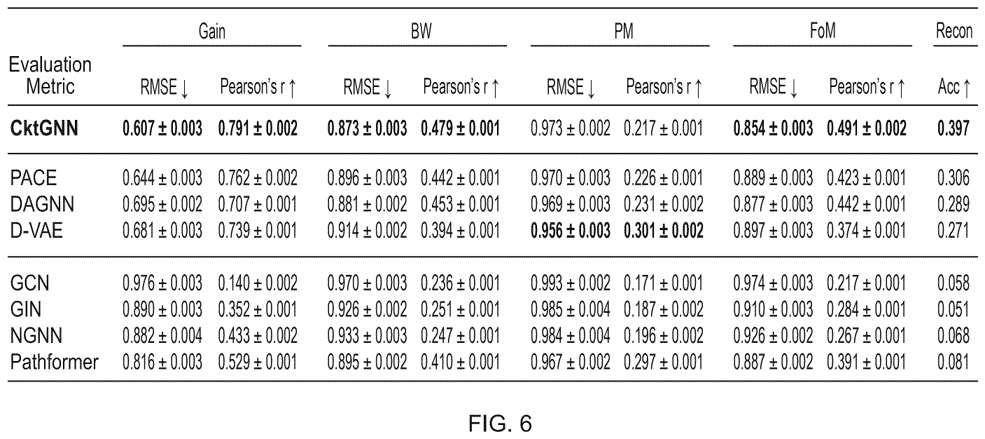

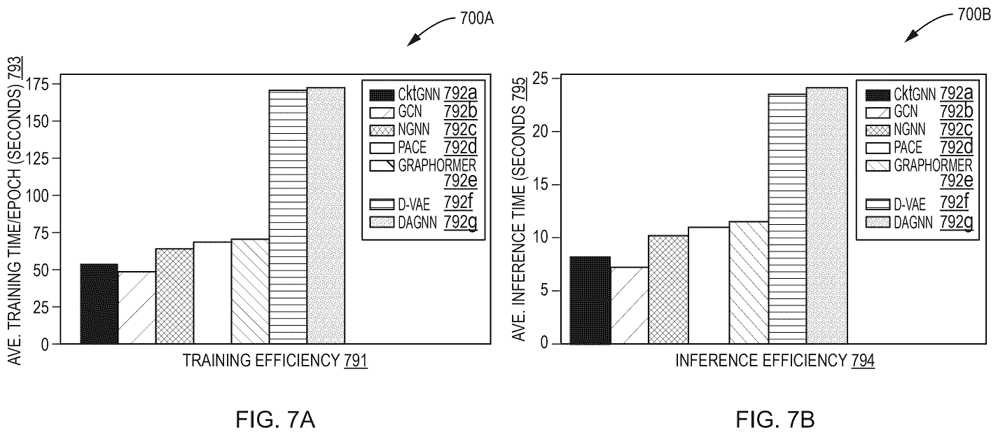

Besides the representation learning ability, efficiency and scalability play critical roles in the model design due to the potential heavy traffic coming into the circuit design automation problem in the real world. In the experiment, a comparison is performed of the average training time per epoch to validate the efficiency of the VAE framework that includes a circuit encoding process and a circuit generation process, while the encoding efficiency itself is tested using the average inference time. FIGS. 7A and 7B illustrate the results.

FIG. 7A is a graph 700A of an example embodiment training efficiency 791, that is, average training time/epoch (seconds) 793 for a CktGNN 792a, GCN 792b, NGGN 792c, PACE 792d, Graphormer 792e, D-VAE 792f, and DAGNN 792g.

FIG. 7B is a graph 700 B of an example embodiment of inference efficiency 794, that is, average inference time (seconds) 795 for the CktGNN 792a, GCN 792b, NGGN 792c, PACE 792d, Graphormer 792e, D-VAE 792f, and DAGNN 792g.

Compared to GRU-based computation encoders (i.e., D-VAE and DAGNN), since CktGNN utilizes simultaneous message passing within each subgraph, it significantly reduces the training/inference time. In addition, it was also found that the extra computation time of CktGNN to fully parallelize encoders (i.e., undirected GNNs like GCN) is marginal.

### 5.4 Effectiveness in Real-World Electronic Circuit Design

Next, a test was performed of the real-world performance of different circuit encoders from two aspects. 1) In a real-world automation process, the circuit generator (i.e., decoder in the VAE framework) is required to be effective to generate proper and novel circuits. Hence, a comparison is performed of the proportion of valid DAGs, valid circuits, and novel circuits of different methods. 2) Also, batch Bayesian Optimization (BO) was performed with a batch size of 50 using the expected improvement heuristic (Jones et al., 1998) and compute the FoM of the detected circuits after 10 iterations.

Table 2, below, summarizes the results.

TABLE 2
Effectiveness in real-world electronic circuit design.

| | Valid DAGs | Valid circuits | Novel circuits | BO |
|---|---|---|---|---|
| Methods | (%)↑ | (%)↑ | (%)↑ | (FoM)↑ |
| CktGNN | 98.92 | 98.92 | 92.29 | 33.436447 |
| PACE | 83.12 | 75.52 | 97.14 | 33.274162 |
| DAGNN | 83.10 | 74.21 | 97.19 | 33.274162 |
| D-VAE | 82.12 | 73.93 | 97.15 | 32.377778 |
| GCN | 81.02 | 72.03 | 97.01 | 31.624473 |
| GIN | 80.92 | 73.17 | 96.88 | 31.624473 |
| NGNN | 82.17 | 73.22 | 95.29 | 32.282656 |
| Graphormer | 82.81 | 72.70 | 94.80 | 32.282656 |

It was found that the proportion of valid circuits generated by the CktGNN-related decoder is significantly higher than other decoders. One potential reason is that CktGNN has an easier topology space to encode and the corresponding decoder can thus better learn the circuit generation rules. It was also found that CktGNN has the best circuit design (generation) ability in the generation process. These observations are significant for real-world applications as the automation tools can perform fewer simulations to be cost-effective and time-efficient. In the end, it was found that CktGNN-based VAE can find the best circuits with the highest FoM and detected circuits may be visualized as disclosed further below in Appendix D.

### 6 Conclusion and Over View

In this disclosure, an example embodiment of a CktGNN has been presented, a two-level GNN model with a pre-designed subgraph basis for the circuit (DAG) encoding problem. Inspired by previous VAE-based neural architecture search routines, the CktGNN was applied based on a VAE framework for the challenging analog circuit design automation task. Experiments on the proposed open circuit benchmark (OCB) show that an example embodiment of an automation tool disclosed herein can address this long-standing challenging problem in a predictivity-effective and time-efficient way. As understood, the proposed CktGNN-based automation framework pioneers the exploration of learning-based methods to simultaneously optimize the circuit topology and device parameters to achieve the best circuit performance. In addition, the proposed OCB is also the first open-source benchmark in the field of analog circuit topology generation and device parameter optimization. Last but not the least, both an example embodiment of a method and benchmark can be generalized to other types of analog circuits with excellent scalability and compatibility.

With the increasing popularity of applying deep learning methods to design industrial digital circuits, such as Google TPU (Mirhoseini et al., “A graph placement methodology for fast chip design,” Nature, 594 (7862): 207-212, Jun2021) and Nvidia GPU (Khailany et al., “Accelerating Chip Design With Machine Learning,” IEEE Micro, 40 (6): 23-32, 2020), the attention paid to analog circuit design automation will be unprecedented as analog circuits are a critical type of ICs to connect the physical analog world and modern digital information world. In a nutshell, it is believed that deep learning (especially graph learning)-based analog circuit design automation is an important rising field, which is worthy of extensive explorations and interdisciplinary collaborations.

### 8 Reproducibility Statement

An example embodiment may be based on Theorem 3.2, and the complete proof of the Theorem is available in Appendix C, disclosed further below. Furthermore, a proposed circuit encoder, CktGNN, is constructed upon the two-level GNN framework with a pre-designed subgraph basis, hence it was compared with the general two-level GNN in Section 3.2, and the expressive ability is disclosed in Appendix B, disclosed further below. For an open circuit benchmark (OCB), detailed instructions are provided in Appendix A, disclosed below, and provide open-source code in supplementary material, including the circuit generation code and the simulation file for the circuit simulator.

### Appendix A

### Operational Amplifiers (Circuits) and the Corresponding Subgraph Basis

In this work, one type of the most classical analog circuits is taken, i.e., operational amplifiers (Op-Amps), as a non-limiting example to present an example embodiment of a graph learning-based automation framework. In this disclosure, the question of interest is whether given a group of Op-Amp circuit specification that are required by a particular application, how to use a graph learning-based automation method to find a proper Op-Amp topology and the corresponding optimal device parameters to achieve the desired circuit specifications? However, an ultimate goal may be to generalize this method to design various analog circuits and even radio-frequency and millimeter-wave circuits.

For an Op-Amp, it has many circuit specifications. Four main specifications are picked up, i.e., DC gain (A), bandwidth (BW), phase margin (PM), and power consumption (P) in this project. All these specifications can be simulated by using circuit simulators or derived by using a simplified behavioral model of Op-Amps.

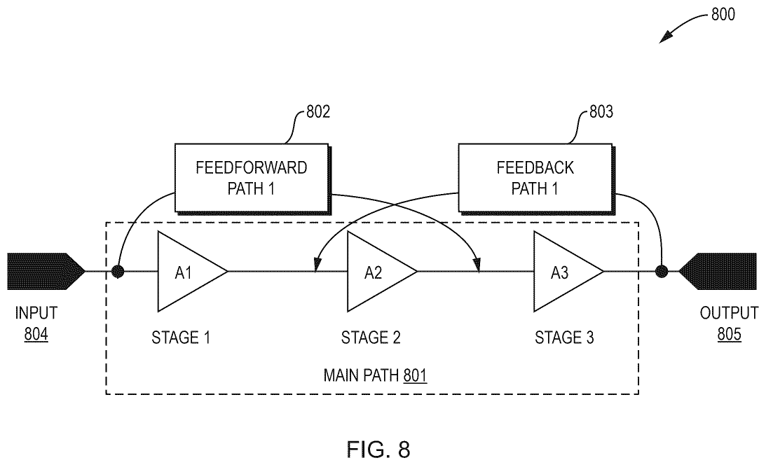

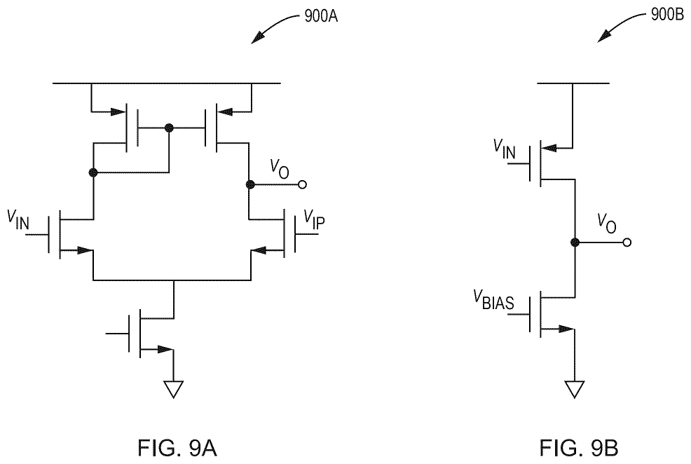

FIG. 8 is schematic diagram 800 of an example embodiment of a three-stage operational amplifier (Op-Amp), which includes the main path 801, several feed-forward paths (e.g., feed-forward path1 802), and several feedback paths (e.g., feedback path 1 803) to provide an output 805 to an input 804. In the main path 801, there are three single-stage Op-Amps, i.e., A1, A2, and A3. The total gain of the three-stage Op-Amp is the product of the gain of each single-stage Op-Amp. To make the Op-Amp more stable, the feed-forward and feedback paths are used to realize the compensation schemes. Each of these paths is implemented with electronic circuits, e.g., single-stage Op-Amps, resistor, and capacitor circuits. Note that, the forward and feedback paths are versatile. FIG. 8 just shows a very simple example. In addition, each single-stage Op-Amp could have many different topologies. For example, FIGS. 9A and 9B show some single-stage Op-Amps with various topologies.

FIG. 9A is a schematic 900A of an example embodiment of a differential Op-Amp.

FIG. 9B is a schematic 900B of an example embodiment of a single-ended Op-Amp.

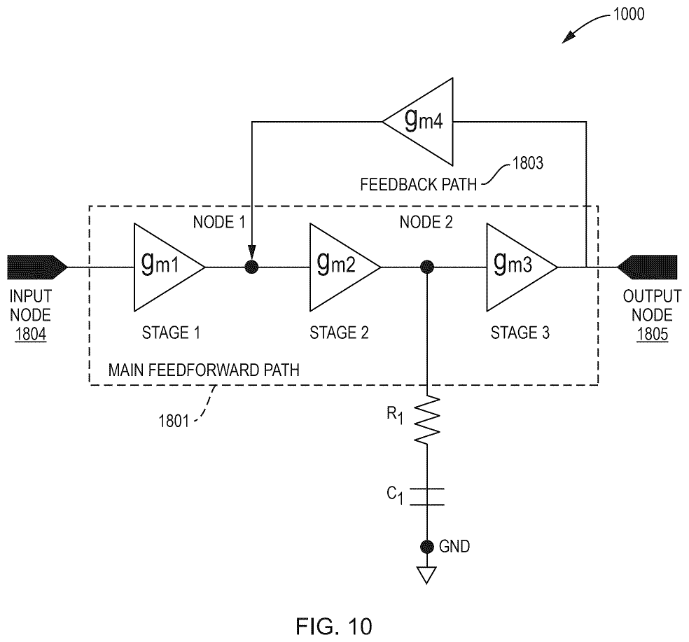

Due to the different topologies of single-stage Op-Amps and various compensation schemes, the design space (e.g., topology space and device parameter space) of three-stage Op-Amps is, thus, very large. The manual process adopted by a human designer is very time-consuming. That is why graph learning-based methods come here. The design of three-stage Op-Amp may be formulated as a graph generation and optimization problem. In this way, an example embodiment can automate the design process. Therefore, the first step is to model the circuit as a graph, as disclosed below with regard to FIG. 10.

FIG. 10 is a schematic diagram 1000 of an example embodiment of graph mapping of a three-stage Op-Amp including a main feedforward path 1801 and a feedback path 1803. The schematic diagram 1000 includes an input node 1804 and an output node 1805. The topology of the three-stage Op-Amp may be mapped into a graph with five nodes: input node, node 1, node 2, output node, and GND node. The edge connecting two nodes can be a single-stage Op-Amp (i.e., transconductance stage, gₘᵢ), resistor (R) or capacitor (C), or a combination of them, as disclosed below.

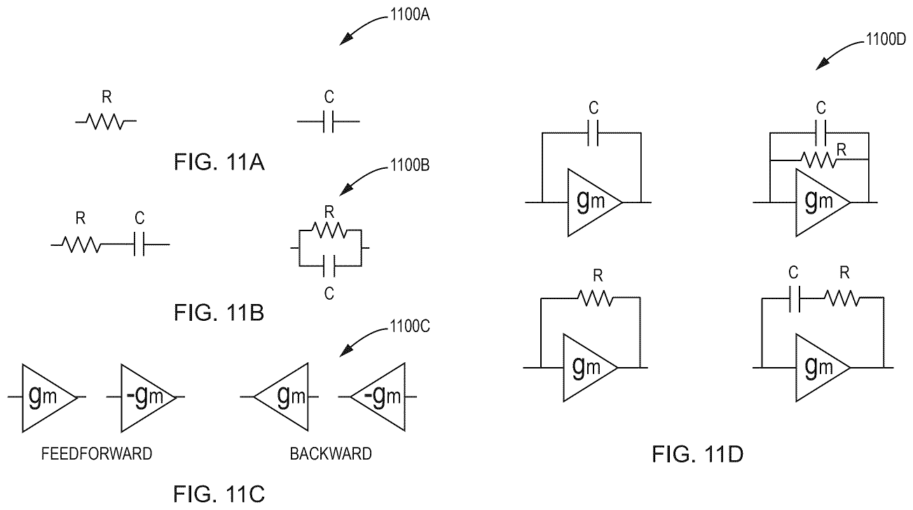

FIGS. 11A-D are schematic diagrams (1100A, 1100B, 1100C, 1100D) of example embodiments of a subgraph basis for operational amplifiers. From the perspective of designing a three-stage Op-Amp, there are 24 types of (existing) connections between every two nodes in the circuit graph shown in FIG. 10:
Only single C or R connection (FIG. 11A, 2 types)
C and R connected in parallel or serial (FIG. 11B, 2 types)
A single-stage Op-Amp (gₘ) with different polarities (positive, +gₘ, or negative, −gₘ) and directions (feedforward or feedback) (FIG. 11C, 4 types); and
A single-stage Op-Amp (gₘ) with C or R connected in parallel or serial (FIG. 11D, 16 types); note that here only the single-stage Op-Amp is taken with feedforward direction and positive polarities as an example.

To simplify the graph learning process, the role of nodes and edges is converted (except for the input node and output node) in FIG. 10, then the FIG. 11A-D, which illustrates the edge types in the original graph, now presents a subgraph basis [symbol] for the operational amplifier.

Given the pre-designed subgraph basis [symbol] , a total order o is defined on subgraphs in [symbol] to guarantee that circuits are injectively represented as DAGs G′. Basically, for subgraphs of size 1, o(gₘ)>o (R)>o(C), and gₘ are set with feedforward direction and positive polarity as a prior order than gm with backward direction and negative polarity. For subgraphs of size larger than 1, the order of subgraphs is firstly dependent on the number of nodes in the subgraph. Then, for subgraphs of the same size, the one with a parallel connection is prior to that with a series connection. In the end, if the connection type is also the same, the order of subgraphs is determined by lexicographically sorting the order of nodes in subgraphs.

### Expressiveness and Total Order on Nodes

Various node orderings have been adopted in encoders for the DAG encoding problem, and node ordering is especially important for auto-regressive models. For instance, S-VAE, D-VAE and DAGNN use topological ordering, PACE and GRAN (Liao et al., “Efficient graph generation with graph recurrent attention networks,” Advances in neural information processing systems, 32, (2019) use canonical ordering, and graphRNN (You et al., “Graphrnn: Generating realistic graphs with deep auto-regressive models,” In International Conference on Machine Learning, pp. 5708-5717. PMLR, 2018) uses BFS ordering. The key of developing powerful DAG encoders is to make sure that node-order dependent encoding process can injectively map non-isomorphic DAGs (or different computation of DAGs) to different embeddings in the vectorial space, and experimental results in prior works (PACE, D-VAE, DAGNN) have confirmed the claim on general DAG encoding tasks, such as NAS (neural architecture search) and Bayesian network structure learning. In summary, PACE can injectively encode the structure of DAGs by linearizing DAGs as sequences according to the canonical ordering, while D-VAE and DAGNN can injectively encode computation of DAGs following an RNN-based directed message passing. Compared with these methods, S-VAE and GraphRNN-like encoder (GraphRNN is originally designed as a pure generative model, yet it can be extended to a BFS-order based DAG encoder following the idea of S-VAE, and details are available in the ablation study section of PACE) fail to injectively encode structure nor computation of DAGs as both topological ordering and BFS ordering are not unique. As a result, PACE, D-VAE, and DAGNN significantly outperforms S-VAE and GraphRNN.

Following the above analysis, it was found that the expressive ability of CktGNN is independent of the domain specific total ordering of nodes. Basically, total ordering of nodes only determines the order of subgraphs (i.e. o) in the subgraph basis [symbol] (see the last paragraph in Appendix A). When basis [symbol] satisfies the conditions in Theorem 3.2, there exists an injective graphilizer f, and f can be formulated as Appendix C suggests. Hence, for any given order o, the input graph G is injectively mapped to f(G), based on which CktGNN performs the two-level GNNs. Then, if both the inner GNNs and outer directed message passing are injective, CktGNN can injectively map f(G) to embeddings in the vectorial space, as injective functions follow the transitive property. Hence, for any order o on subgraph basis [symbol] , the overall encoding process can injectively map G to embeddings.

Although the expressive ability is not affected by the node ordering, the complexity of topology search space is dependent on it. When different orders are used: o1 and o2, the graphilizer f will map G to different transformed graphs fₒ₁ (G) and fₒ₂ (G), where fₒ₁ (G) and fₒ₂ (G) may contain different numbers of subgraphs. Hence, the numbers of connections between subgraphs to encode in the outer message passing are different.

In the studied op-amp circuits automation problem, it was found that the order of subgraphs in basis [symbol] will not affect the transformation from circuits G to transformed graphs f(G) (though it is not true for the general problems) due to the property of op-amp circuits. For instance, when the order of C and R (i.e., from o(R)>o(C) to o(C)>o(R)) is reversed, the order of subgraphs ‘C parallel gm’ and ‘R parallel gm’ will also be reversed (i.e., from o(‘R parallel gm’)>o(‘C parallel gm’) to o(‘C parallel gm’)>o(‘R parallel gm’)). However, when the reversed subgraph order affects the transformation from G to f(G), it was found that the gm, C, and R should be connected in parallel, which means that they formulate another subgraph ‘gm parallel R parallel C’ of larger size in the basis [symbol] , which means that the graphilizer f should choose subgraph ‘gm parallel R parallel C’ instead of decomposing it to smaller subgraphs. An example embodiment may also empirically evaluate the effect of domain specific total ordering of nodes on the dataset, and it was found that 0 of 10000 circuits G have different transformed graphs f(G) when the order of C and R were reversed.

### Appendix B

Expressive Ability of Two-Level GNN with a Subgraph BSIS

Though various GNN models have been proposed, (Atwood & Towsley, “Diffusion-convolutional neural networks,” In Advances in Neural Information Processing Systems, pp. 2001-2009,2016; Verma & Zhang, “Graph capsule convolutional neural networks.” arXiv preprint arXiv: 1805.08090, 2018; Niepert et al., “Learning convolutional neural networks for graphs,” In International conference on machine learning, pp. 2014-2023. PMLR, 2016), most follow the message passing scheme (Gilmer et al., “Neural message passing for quantum chemistry,” In International Conference on Machine Learning, pp. 1263-1272. PMLR, 2017). Message passing GNNs (MPGNNs) implicitly leverage the inductive bias in the graph topology by iteratively passing messages between each node and its neighbors to extract a node embedding that encodes the local substructure. The message passing scheme shows impressive graph representation learning ability to extract highly expressive features representing the local structure information in a graph. MPGNNs show a close relationship with the WL test, and (Xu et al., “How powerful are graph neural networks?” arXiv preprint arXiv: 1810.00826, 2018) has proven that they are at most as powerful as the WL test for distinguishing graph structures, which limits the expressive power of message passing GNNs. To improve the expressiveness of message passing GNNs, a plug-and-play framework, NGNN (Zhang & Li, “Nested graph neural networks,” Advances in Neural Information Processing Systems, 34, 2021), is proposed to learn substructures where standard message passing scheme fails to discriminate. NGNN uses a two-level GNN framework that uses an inner GNN to learn the representation of extracted subgraphs around each node to embed the substructures, instead of rooted subtrees, thereby efficiently distinguishing almost all d-regular graphs.

Corollary B.1 By selecting proper subgraph basis [symbol] and order function o, the expressiveness of the two-level GNN framework with subgraph basis [symbol] can be: 1) strictly more powerful than message passing GNNs; 2) as powerful as nested GNN in distinguishing n-sized r-regular graphs.

When the subgraph basis [symbol] contains all subgraphs of depth 1, the two-level GNN with [symbol] is equivalent to a general message passing framework. If rooted subgraphs are added with a height larger than 1, message passing in inner GNNs will be applied to added rooted subgraphs to extract additional distance features (Li et al., “Distance encoding-design provably more powerful gnns for structural representation learning,” arXiv preprint arXiv: 2009.00142, 2020) to provide further distinction ability. On the other hand, when the subgraph basis contains all height-k rooted subgraphs and the order function o defines a partial order dependent on the root node v, then the two-level GNN with subgraph basis [symbol] is essentially NGNN framework.

The Corollary indicates that it is possible to manipulate the subgraph basis to balance the trade-off between the complexity and the expressiveness of the two-level GNN framework. The problem is left for the future to incorporate the subgraph selection progress into the end-to-end learning framework for the general graph learning tasks. In this work, the focus is on the circuit (DAG) optimization problem, where the ordered subgraph basis is known, and it was shown that it can be used to reduce the (topology) search space size of the optimization problem.

### Appendix C

### Proof of Theorem 3.2

It's straightforward that the f can convert input DAG G to some transformed DAGs G′₁, . . . . G′ₘ if basis [symbol] contains every of size 1. Then one can identify the unique f by following two rules:
(1) Then the output of f should minimize the number of nodes (subgraphs used in the basis [symbol] ) in the transformed graph G′. That is. f(G)=G′=arg min_{i=1,2 , . . . m} |G′i|
(2) If there exists two transformed subgraphs G′ᵢ and G′ⱼ such that |G′ᵢ|=|G′ⱼ|=arg min_{i=1,2 . . . m} |G′ₗ|=K, then both G′ᵢ and G′ⱼ are represented as K subgraphs in basis [symbol] g₁ⁱ, . . . gₖⁱ. These are denoted as K subgraphs as G′_{i,1}, G′_{i,2} . . . , G′_{i,k}, and G′_{j,1}, G′_{j,2}, . . . , G′_{j,K}, then one can sort o(G′_{i,1}), o(G′_{i,2}), . . . , o(G′_{i,K}), to provide G′ᵢ a ordered tuple tᵢ of size K, and sort o (G′_{j,1}), o(G′_{j,2}), . . . , o(G′_{j,K}) to provide G′j a ordered tuple tⱼ of size K. Then the output of f is given by:

$$f ( G ) = \{ \begin{matrix}{G}_{i}^{′} , & {t}_{i} > {t}_{j} \\ {G}_{j}^{′} , & {t}_{j} > {t}_{i}\end{matrix}$$

where > denotes the lexicographical sorting operation.

The above rules ensure that the graphitized f can injectively select subgraphs in the basis [symbol] to formulate the transformed DAG G′. Then, since each subgraph in [symbol] only has a single node one node to be the head (tail) of a directed edge whose tail (head) is outside the subgraph, the connections between subgraphs are uniquely dependent on the input DAG G. Furthermore, as connections between nodes within each subgraph in [symbol] are fixed, the order of nodes in input DAG is uniformly encoded in the transformed DAG G′.

### Appendix D

### Experiment Details and Additional Results

### Model Configurations

For non-limiting examples, in the experiment, message passing GNNs (i.e., GCN and GIN) contain 3 graph convolution layers and use mean pooling to read out graph-level representation. NGNN uses a rooted subgraph height h=3 and takes GIN with l=3 layers as the base GNN. In Transformer-based models (i.e., Graphormer and PACE), the number of Transformer encoder layers is 5 and it plays multi-head attention with 6 heads. DAGNN uses two-layer directed graph convolutions. Experiments were implemented on 12G TeslaP100 and Geforce GTX 1080 Ti, and 5 independent trials are implemented when the mean and standard deviation are reported.

### Bayesian Optimization Results

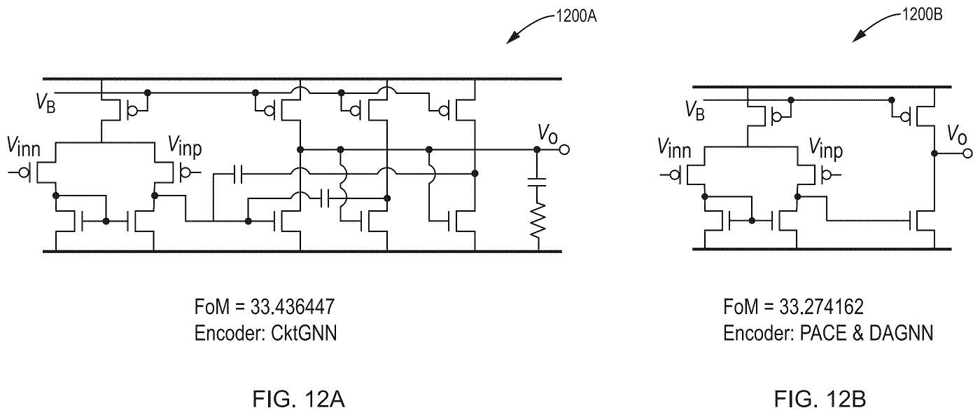

In the experiment, the Bayesian optimization approach was taken and the FoM score was optimized over the (latent) vectorial space generated by the DAG encoder. FIGS. 12A and 12B, disclosed below, include the results.

FIGS. 12A and 12B are schematic drawings of example embodiments of optimal circuits (1200A, 1200B) detected by Bayesian Optimization. Optimization on the latent space by CktGNN yields a circuit with the largest FoM score than competitive DAG encoders (or GNN for undirected graphs).

### Appendix E

More Details about Training and Evaluation

### Training Methodology

The proposed CktGNN can be trained in a supervised fashion, or in the VAE framework. When trained with supervised learning, the loss function is formulated with the target value and the output representation of CktGNN. On the other hand, CktGNN can also be trained in a VAE framework such as D-VAE, DAGNN, and PACE. In the VAE architecture, CktGNN is taken as the DAG encoder. Two fully connected (FC) layers take the output representation of CktGNN as inputs to predict the mean and variance of the approximated posterior distribution in the evidence lower bound (ELBO) (Kingma & Welling, “Auto-encoding variational bayes,” arXiv preprint arXiv: 1312.6114, 2013). The decoder is formulated as the decoder of D-VAE to generate transformed DAGs G′ from the latent space. That is, the decoder uses the same undirected message passing as CktGNN to learn intermediate node and graph states zᵥ′. For the i^{th} generated node v′ᵢ in G′, MLPs are used to predict the subgraph type in the basis [symbol] and the existence of directed edges (v′ⱼ, v′ᵢ) for v′ⱼ∈G′, j=1, 2, . . . , i−1. In addition, given the predicted subgraph type, the topology within the subgraph is known. Therefore, the decoder only needs to use MLPs to predict the node features within the subgraph based on the current graph state z_{v′}.

In the training methodology, a VAE architecture is used, and the VAE loss is formulated as reconstruction loss +α KL divergence, where α is set to be 0.005 as prior works (i.e. Grammer variational autoencoder (Kusner et al., “Grammar variational autoencoder,” In International conference on machine learning, pp. 1945-1954. PMLR, 2017), D-VAE, PACE). In the training process, a mini-batch stochastic gradient descent with a batch size of 64 was performed. Models were trained for 200 epochs. The initial learning rate is set as 1E-4, and a schedule used to modulate the changes of the learning rate over time such that the learning rate will shrink by a factor of 0.1 if the training loss is not decreased for 20 epochs.

When evaluating the circuit design ability in section 5.4, two metrics were used: Valid circuits and Novel circuits, to measure the circuit design (generation) effectiveness. To calculate these values, 1000 random points were sampled in the latent vectorial space from a (prior) standard normal distribution and each point decoded for 10 times. Then the proportion of valid circuits and novel circuits not seen in the training sets was computed. A generated circuit is valid if it satisfies following three criteria: (1) It has only one input node and one output node; (2) The generated circuit (directed graph) is a DAG (i.e., there is no cycle); (3) In the main path, there is no R node nor C node. The last criterion is consistent with the design rules of operational amplifiers (Op-Amps), and more details are available in Appendix A, disclosed above.

### Appendix F

### More Details About Decoder

Basically, the decoder is also based on the CktGNN framework where the GRU-based directed message passing (introduced in D-VAE) is used as the outer GNN. Given a point z in the latent vectorial space, an MLP is used to map z to h₀ as the initial hidden state. Next, the decoder constructs the circuits subgraph by subgraph, where subgraphs are from the known subgraph basis [symbol] . Specifically, for the ith subgraph v′ᵢ, an MLP fsubg(hv′ᵢ−1) is used to compute the subgraph type distribution and sample the subgraph type v′ᵢ. Then the hidden state representation h_{v′}_{_{i−1}} can be updated using the CktGNN framework based on current circuit (DAG). Given the predicted subgraph type, the topology within the subgraph is known, thus the decoder only needs to use MLPs to predict the node features within the subgraph based on h_{v′}_{_{i−1}} . In the end, for previous subgraph v′ⱼ such that j<i, an MLP f_{edge}(h_{v′}_{ⱼ}m h_{v′}_{ᵢ}) is used to predict the probability of connection between v′ and v′. These actions are repeated until the generated subgraph type is an output type.

FIG. 13 is a block diagram of an example of the internal structure of a computer 1300 in which various embodiments of the present disclosure may be implemented. The computer 1300 contains a system bus 1352, where a bus is a set of hardware lines used for data transfer among the components of a computer or digital processing system. The system bus 1352 is essentially a shared conduit that connects different elements of a computer system (e.g., processor, disk storage, memory, input/output ports, network ports, etc.) that enables the transfer of information between the elements. Coupled to the system bus 1352 is an I/O device interface 1354 for connecting various input and output devices (e.g., keyboard, mouse, displays, printers, speakers, etc.) to the computer 1300. A network interface 1356 allows the computer 1300 to connect to various other devices attached to a network (e.g., global computer network, wide area network, local area network, etc.). Memory 1358 provides volatile or non-volatile storage for computer software instructions 1360 and data 1362 that may be used to implement embodiments of the present disclosure, where the volatile and non-volatile memories are examples of non-transitory media. Disk storage 1364 provides non-volatile storage for computer software instructions 1360 and data 1362 that may be used to implement embodiments of the present disclosure. A central processor unit 1366 is also coupled to the system bus 1352 and provides for the execution of computer instructions.

An example embodiment disclosed herein may employ hardware, software, firmware, electronic control component, processing logic, and/or processor device, individually or in any combination, including without limitation: an application specific integrated circuit (ASIC), a field-programmable gate-array (FPGA), an electronic circuit, a processor and memory that executes one or more software or firmware programs, and/or other suitable components that provide the described functionality.

Example embodiments disclosed herein may be configured using a computer program product; for example, controls may be programmed in software for implementing example embodiments. Further example embodiments may include a non-transitory computer-readable medium that contains instructions that may be executed by a processor, and, when loaded and executed, cause the processor to complete methods described herein. It should be understood that elements of the block and flow diagrams may be implemented in software or hardware, such as via one or more arrangements of circuitry of FIG. 13, disclosed above, or equivalents thereof, firmware, a combination thereof, or other similar implementation determined in the future.

In addition, the elements of the block and flow diagrams described herein may be combined or divided in any manner in software, hardware, or firmware. If implemented in software, the software may be written in any language that can support the example embodiments disclosed herein. The software may be stored in any form of computer readable medium, such as random-access memory (RAM), read-only memory (ROM), compact disk read-only memory (CD-ROM), and so forth. In operation, a general purpose or application-specific processor or processing core loads and executes software in a manner well understood in the art. It should be understood further that the block and flow diagrams may include more or fewer elements, be arranged or oriented differently, or be represented differently. It should be understood that implementation may dictate the block, flow, and/or network diagrams and the number of block and flow diagrams illustrating the execution of embodiments disclosed herein.

The teachings of all patents, published applications, and references cited herein are incorporated by reference in their entirety.

While example embodiments have been particularly shown and described, it will be understood by those skilled in the art that various changes in form and details may be made therein without departing from the scope of the embodiments encompassed by the appended claims.

What is claimed is:

1. A computer-implemented method for training a circuit topology generator, the computer-implemented method comprising:
transforming a training circuit topology into a hierarchical graph in a high-dimensional data space, nodes of the hierarchical graph corresponding to selected subgraphs forming a subgraph basis, the selected subgraphs of the subgraph basis representing circuit elements of the training circuit topology;
converting the hierarchical graph into a directed acyclic graph (DAG) to be processed by a circuit graph neural network (CktGNN) into a latent space, the latent space being a lower-dimensional data space relative to the high-dimensional data space;
transforming the DAG into an estimated circuit topology via the circuit topology generator; and
training the CktGNN and circuit topology generator based on differences between the training circuit topology and the estimated circuit topology toward causing the circuit topology generator to converge on the training circuit topology.

2. The computer-implemented method of claim 1, wherein the training circuit topology is a schematic of an analog circuit, and wherein the selected subgraphs represent analog circuit elements.

3. The computer-implemented method of claim 1, wherein converting the hierarchical graph into the DAG includes generating nodes of the DAG and wherein the nodes generated represent non-overlapping combinations of the selected subgraphs.

4. The computer-implemented method of claim 1, further comprising encoding the nodes of the hierarchical graph with respective features of the circuit elements represented by the selected subgraphs corresponding thereto, wherein the respective features are associated with the selected subgraphs in the subgraph basis, and wherein the respective features represent respective electrical characteristics.

5. The computer-implemented method of claim 4, wherein encoding the nodes includes embedding text representing the respective features.

6. The computer-implemented method of claim 1, wherein the latent space is a vectorial space and wherein the computer-implemented method further comprises:
encoding the nodes of the hierarchical graph with respective features of the circuit elements represented by the selected subgraphs corresponding thereto;
deriving, via the CktGNN, hidden representations from the respective features encoded in the nodes; and
encoding the hidden representations derived as vectors in the vectorial space.

7. The computer-implemented method of claim 1, wherein transforming the DAG from the latent space to the estimated circuit topology includes:
predicting subgraph types and node features of nodes of the DAG; and
predicting probabilities of connections between the nodes of the DAG via multilayer perceptron (MLP) neural networks.

8. The computer-implemented method of claim 1, wherein the CktGNN includes inner GNNs and an outer GNN and wherein training the CktGNN includes:
independently learning, via the inner GNNs, representations of the selected subgraphs as node embeddings; and
performing, via the outer GNN, directed message passing with the learned node embeddings to learn a representation for an entire graph representing the training circuit topology.

9. The computer-implemented method of claim 1, wherein transforming the DAG into the estimated circuit topology includes:
transforming the DAG into an estimated hierarchical graph in the high-dimensional data space, the estimated hierarchical graph including estimated nodes representing respective subgraphs from the subgraph basis; and
converting the estimated hierarchical graph into the estimated circuit topology by using the subgraph basis to convert the respective subgraphs to corresponding circuit elements.

10. The computer-implemented method of claim 1, further comprising optimizing the DAG in the latent space via at least one optimization method and wherein the at least one optimization method includes at least one of: a Gaussian optimization method, Bayesian optimization method, or other optimization method.

11. A computer-implemented method for automating circuit topology generation, the computer-implemented method comprising:
generating, automatically via a trained circuit topology generator, a circuit topology based on a latent space and subgraph basis, the latent space being a lower-dimensional data space relative to a higher-dimensional data space, the generating including generating a hierarchical graph in the higher-dimensional space, the hierarchical graph includes nodes corresponding to subgraphs of the subgraph basis; and
outputting, by the trained circuit topology generator, the circuit topology generated.

12. A computer-implemented method of claim 11, wherein sampling the latent space includes sampling the latent space, randomly.

13. A computer-implemented method of claim 11, wherein sampling the latent space includes controlling the sampling based on at least one control input and wherein a control input of the at least one control input represents a feature of an electrical circuit element.

14. The computer-implemented method of claim 13, wherein generating the circuit topology includes including a representation of a circuit element with the feature in the circuit topology generated and wherein the circuit topology generated is a schematic.

15. The computer-implemented method of claim 13, wherein the control input is a natural language input, wherein the natural language input is text, and wherein the text is embedded in the latent space.

16. The computer-implemented method of claim 13, wherein generating the circuit topology includes generating the circuit topology for a class of circuit for which the circuit topology generator is trained.

17. The computer-implemented method of claim 15, wherein the circuit topology generated is a novel circuit topology and wherein the novel circuit topology is different from training circuit topologies of a training dataset used to train the circuit topology generator.

18. The computer-implemented method of claim 11, wherein the latent space represents a statistical distribution of learned representations of training circuit topologies of a circuit class and wherein the circuit topology generated is associated with the circuit class.

19. The computer-implemented method of claim 11, wherein the circuit topology generated is an analog circuit topology.

20. A non-transitory computer-readable medium for training a circuit topology generator, the non-transitory computer-readable medium having encoded thereon a sequence of instructions which, when loaded and executed by at least one processor, causes the at least one processor to:
transform a training circuit topology into a hierarchical graph in a high-dimensional data space, nodes of the hierarchical graph corresponding to selected subgraphs forming a subgraph basis, the selected subgraphs of the subgraph basis representing circuit elements of the training circuit topology;
convert the hierarchical graph into a directed acyclic graph (DAG) to be processed by a circuit graph neural network (CktGNN) into a latent space, the latent space being a lower-dimensional data space relative to the high-dimensional data space;
transform the DAG into an estimated circuit topology via the circuit topology generator; and
train the CktGNN and circuit topology generator based on differences between the training circuit topology and the estimated circuit topology toward causing the circuit topology generator to converge on the training circuit topology.
